(19) United States
(12) Patent Application Publication
(10) Pub. No.: US 2010/0230053 A1
(43) Pub. Date: Sep. 16, 2010

(54) PLASMA PROCESSING APPARATUS

(76) Inventor: Ryoji NISHIO, Kudamatsu (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/685,688

(22) Filed: Jan. 12, 2010

(30) Foreign Application Priority Data
Jan. 15, 2009 (JP) PCT/JP2009/050428
Dec. 24, 2009 (JP) 2009-291928

(51) Int. Cl. H01L 21/465

(52) U.S. Cl. 156/345.49; 257/E21.485

(57) ABSTRACT

The invention provides a plasma processing apparatus for subjecting a sample to plasma processing by generating plasma within a vacuum processing chamber 1, wherein multiple sets (7, 7′) of high frequency induction antennas are disposed for forming an induction electric field that rotates in the right direction on an ECR plane of the magnetic field formed within the vacuum processing chamber 1, and plasma is generated via an electron cyclotron resonance (ECR) phenomenon. A Faraday shield 9 for blocking capacitive coupling and realizing inductive coupling between the high frequency induction antenna and plasma receives power supply via a matching box 46 from an output from a Faraday shield high frequency power supply 45 subjected to control of a phase controller 44 based on the monitoring of a phase detector 47-2. Multiple filters 49 short-circuit the high frequency voltage at various portions of the Faraday shield 9 to ground, thereby preventing the generation of an uneven voltage distribution having the same frequency as the plasma generating high frequency.

The present application is based on and claims priorities of PCT International application No. PCT/JP2009/050428 filed Jan. 15, 2009 and Japanese patent application No. 2009-291928 filed on Dec. 24, 2009, the entire contents of which are hereby incorporated by reference.

### BACKGROUND OF THE INVENTION

1. Field of the Invention

The present invention relates to a plasma processing apparatus using inductively-coupled electron cyclotron resonance plasma.

2. Description of the Related Art

In response to the miniaturization of semiconductor devices, process conditions (process window) for realizing a uniform processing result within a wafer plane during plasma processing has become narrower year after year, and the plasma processing apparatuses are required to realize complete control of the process conditions. In order to respond to such demands, apparatuses are required to control the distribution of plasma, the dissociation of process gas and the surface reaction within the reactor with extremely high accuracy.

Currently, a typical plasma source used in such plasma processing apparatus is a high frequency inductively coupled plasma (hereinafter referred to as ICP) source. In an ICP source, at first, high frequency current I flowing through the high frequency induction antenna creates an induction magnetic field H around the antenna, and the induction magnetic field H creates an induction electric field E. At this time, when electrons exist within the space for generating plasma, the electrons will be driven by the induction electric field E to ionize the gas atoms (molecules) and generate ion and electron pairs. The electrons generated in this manner are driven again by the induction electric field E together with the original electrons, causing further ionization. Finally, plasma is generated via avalanche ionization phenomenon. The area where the plasma density is highest is where the induction magnetic field H and the induction electric field E is strongest within the space for generating plasma, that is, the area closest to the antenna. Further, the intensity of the induction magnetic field H and the induction electric field E is characterized in that the intensity attenuates by double the distance with the line of the current I flowing through the high frequency induction antenna set as center. Therefore, the intensity distribution of the induction magnetic field H and the induction electric field E, or the plasma distribution, can be controlled via the shape of the antenna.

As described, the ICP source generates plasma via the high frequency current I flowing through the high frequency induction antenna. In general, when the number of turns of the high frequency induction antenna is increased, the inductance increases and the current drops, but the voltage increases. When the number of turns is reduced, in contrast, the voltage drops but the current increases. In designing the ICP source, the preferable level of current and voltage is determined based on various reasons, not only from the viewpoint of uniformity, stability and generation efficiency of plasma, but also from the viewpoint of mechanical and electrical engineering. For example, the increase of current causes problems such as heat generation, power loss caused thereby, and current-proof property of the variable capacitor used in the matching network. On the other hand, the increase of voltage causes problems such as abnormal discharge, the influence of capacitive coupling between the high frequency induction antenna and plasma, and the dielectric-strength property of the variable capacitor. Therefore, the designers of ICP sources determine the shape and the number of turns of the high frequency induction antenna considering the current proof property and the dielectric-strength property of electric elements such as the variable capacitor used in the matching circuit, the cooling of the high frequency induction antenna and the problem of abnormal discharge.

Such ICP source has an advantage in that the intensity distribution of the induction magnetic field H and the induction electric field E created by the antenna, that is, the distribution of plasma, can be controlled by the winding method and the winding shape of the high frequency induction antenna. Based thereon, ICP sources have been devised in various ways.

One actual example is a plasma processing apparatus for processing a substrate on a substrate electrode using an ICP source. Regarding such plasma processing apparatus, Japanese patent application laid-open publication No. 8-83696 (patent document 1) discloses forming the high frequency induction antenna in which a portion or all of the antenna is a multi-spiral shape, which enables to realize a more uniform plasma, reduce the deterioration of electric power efficiency of a matching parallel coil of the matching circuit for the high frequency induction antenna, and minimize temperature increase.

Another structure has been proposed in which a plurality of completely same high frequency induction antennas are disposed in parallel at fixed angles. For example, Japanese patent application laid-open publication No. 8-321490 (patent document 2) discloses disposing three lines of high frequency induction antennas at 120° intervals, so as to improve the circumferential uniformity. The high frequency induction antenna can be wound vertically, wound on a plane, or wound around a dome. If a plurality of completely same antenna elements are connected in parallel in a circuit-like manner as disclosed in patent document 2, there is an advantage that the total inductance of the high frequency induction antenna composed of multiple antenna elements can be reduced.

Furthermore, Japanese patent application laid-open publication No. 2005-303053 (patent document 3) discloses connecting two or more antenna elements having the same shape in parallel in a circuit-like manner to form the high frequency induction antenna, wherein the antenna elements are arranged either concentrically or radially so that the center of the antenna elements corresponds to the center of the object to be processed, the input ends of the respective antenna elements are arranged at angular intervals determined by dividing 360° by the number of antenna elements, and the antenna elements are formed to have a three-dimensional structure in the radial direction and the height direction.

In contrast to the ICP source, an electron cyclotron resonance (hereinafter referred to as ECR) plasma source is a plasma generating device utilizing the resonance absorption of electromagnetic wave by electrons, having superior characteristics in that the absorption efficiency of electromagnetic energy is high, the igniting property is high, and high density plasma can be obtained. Currently provided plasma sources utilize microwave (hereinafter referred to as μ wave) (2.45 GHz) or electromagnetic wave of the UHF and VHF bands. In order to radiate electromagnetic wave into the discharge space, electrodeless discharge using waveguides is mainly used for μ wave (2.45 GHz), whereas parallel plate-type capacitive coupling discharge using capacitive coupling between the electrode radiating electromagnetic wave and plasma is mainly used for UHF and VHF.

There also is a plasma source that utilizes an ECR phenomenon using the high frequency induction antenna. In that case, plasma is generated using waves accompanying a kind of ECR phenomenon called a whistler wave. Whistler wave is also called a helicon wave, and a plasma source utilizing this phenomenon is also called a helicon plasma source. According to the arrangement of the helicon plasma source, for example, a high frequency induction antenna is wound around the side of a cylindrical vacuum chamber, and a high frequency power having a relatively low frequency, such as 13.56 MHz, is applied, and a magnetic field is further applied. At this time, the high frequency induction antenna generates electrons that rotate in the right direction for half a cycle of 13.56 MHz, and electrons that rotate in the left direction for the remaining half of each cycle of 13.56 MHz. Out of these two kinds of electrons, the mutual interaction between the electrons rotating in the right direction and the magnetic field cause the ECR phenomenon. However, the helicon plasma source has various problems, such as the time in which ECR phenomenon is caused is limited to half a cycle of the high frequency, the location in which ECR is caused is dispersed and the absorption length of electromagnetic wave is long so that a long cylindrical vacuum chamber is required and plasma uniformity is difficult to achieve, and it is difficult to control the plasma characteristics (such as the electron temperature and gas dissociation) appropriately since the plasma characteristics is changed in a step-like manner, so it is not suitable for industrial use.

A vertically long vacuum reactor specifically used with a helicon plasma source have been proposed (refer for example to patent document 5: U.S. Pat. No. 3,269,853). However, according to the art disclosed in the document, no high frequency induction antenna is used, and helicon wave is generated by controlling the phase of the voltage applied to patch electrodes capacitively coupled with plasma. Further, in order to compensate for the disadvantages of controllability of plasma distribution, a group of electrodes including two or more sets of electrodes is arranged with an interval corresponding to the function of the wavelength of the helicon wave along the vertical vacuum chamber. However, regardless of whether an inductively coupled antenna is used or capacitively coupled patch electrodes is used, the use of the helicon wave inevitably requires a vertical long vacuum reactor having deteriorated plasma controllability. This feature is reflected in patent document 5. Further, the attempt to improve the plasma controllability of the vertical long vacuum reactor requires an extremely complicated electrode and magnetic field arrangement, which is also reflected in patent document 5.

There are multiple ways to create a rotating electric field so as to generate electrons rotating in the right direction. A simple method has been known using a patch antenna taught for example in patent document 5, wherein n-number of (for example, four) patch-like antennas (with small planes having circular or square shapes) are arranged on a circumference, and the phases of supplied voltages having an electromagnetic wave frequency to be radiated are displaced by π/n (for example, π/4), according to which a right-direction circularly polarized electromagnetic wave is radiated.

First, we will describe the method for actively generating an electric field that rotates in the right direction. If an active antenna exists, both a near field (electric field and magnetic field) and a far field (electromagnetic wave) are formed near the antenna. The intensity of the fields depends on the design and the method of use of the antenna. At this time, if the plasma and the antenna are capacitively coupled, the main process of power transmission to plasma will be the electric field (near field). If the plasma and the antenna are inductively coupled, the main process of power transmission to plasma will be the magnetic field (near field). If neither capacitive coupling nor inductive coupling is realized, the main process of power transmission to plasma will be the far field. The methods for generating an electric field that rotates in the right direction using electromagnetic wave radiation, electric field, and magnetic field will now be described.

### (1) Electromagnetic Wave Radiation (Far Field)

Far field refers to an electromagnetic wave that can be transmitted to a far distance. This method is divided into two cases, one case related to discharging the electromagnetic field having a circularly polarized wave that is actively rotated in the right direction, the other case related to using right-direction circularly polarized wave components contained in the electromagnetic wave without actively causing a right-direction circularly polarized wave. The aforementioned method of arranging n-number of patch antennas belongs to the former case, and the prior art electrodeless ECR discharge using μ wave belongs to the latter case. The plasma and the antenna are not actively connected, so that the near field does not come in the way. The radiated electromagnetic wave is simply entered to the plasma. It is known that general antennas such as patch antennas or dipole antennas (refer to patent document 4; Japanese patent application laid-open publication No. 2000-235900: however, this example does not actively rotate the electromagnetic field in the right direction) can be used. In other words, the following points (A) (B) and (C) are true according to this method.

(A) Power is applied to the antenna (electrode). Resonance of the antenna is actively used in many cases. When resonance is not used, the radiation efficiency of electromagnetic wave is deteriorated, and it cannot be applied to actual use. Since the radiated electromagnetic wave does not actively head toward the plasma (the wave is basically transmitted to a far distance, so it is scattered to various areas), it is not absorbed so much in plasma, so it cannot be applied to transferring a large amount of power. In order to transfer a large amount of power, waveguides having restricted propagation direction of electromagnetic wave are used in many cases. However, since the size of the waveguide depends on the wavelength of the electromagnetic wave, and since the waveguide size becomes too large when frequencies smaller than μ wave are used, the waveguide cannot be used in many cases.
(B) If an electrode (antenna) is used instead of waveguides, a terminal for applying power to the electrode must be provided. A terminal for grounding the electrode may or may not exist, depending on how the resonance of antenna is caused.
(C) Regardless of whether the antenna exists, the percolation threshold of the electromagnetic field radiated in the plasma depends on the cutoff density nc (m⁻³), and in this case, the electromagnetic wave penetrates the plasma to the skin depth. The skin depth is 138 mm when the resistivity of plasma at 200 MHz is 15 Ωm, which is longer by a digit than the sheath (smaller than a few mm). In other words, it penetrates further into the plasma compared to the case of capacitive coupling mentioned hereafter.

The relationship between the frequency f of electromagnetic wave and the cutoff density nc is illustrated in FIG. 30. In the area equal to or smaller than μ wave, the cutoff density n_{c} is generally smaller than the industrially used plasma density (10¹⁵⁻¹⁷ m⁻³). In other words, the electromagnetic wave smaller than μ wave cannot propagate freely through normal plasma, and penetrates to the skin depth.

### (2) Electric Field (Near Field)

In order to generate an electric field, an active electrode for generating near field (electric field) is necessary, and patch electrodes (refer for example to patent document 5) or parallel plate-type electrodes can be used. In this case, the electric field (voltage generated in the electrode) must be strong (high), so that the load of the electrode must be of high impedance. In other words, the electrode used in this example must be capacitively coupled with plasma, but designed so as not to be coupled with grounded components as much as possible. That is, it is normally not possible to ground even a portion of the electrode, or ground the same via capacitors or coils. Since the electric field is a near field, a large amount of power can be transferred to the plasma with high efficiency by devising the positional relationship between the electrode and plasma, but in order to increase capacitive coupling, a sufficient area (large capacitance) is required with respect to the plasma. Since capacitive coupling between the electrode and plasma is utilized, not only an antenna (electrode that radiates electromagnetic wave) but also an electrode (similar to that of a capacitively coupled parallel plate plasma source) that generates a simple electric field (near field) having only a weak ability to radiate electromagnetic wave can be used.

The following points can be said with respect to this method.

(A) Voltage is applied to the electrode. Especially, when a right-direction circularly polarized wave is actively generated, phase-controlled voltage is applied to the electrode.
(B) The electrode only includes a terminal through which voltage is applied, and no other terminal, such as a terminal for grounding the electrode, exists.
(C) The capacitively coupled electric field is shielded by the collective motion of electrons (sheath). Such shielding can be prevented by restricting the movement of electrons by applying a magnetic field perpendicular to the electric field of the sheath. In another expression, when the movement of electrons is restricted, the wavelength of the electric field within the plasma can be extended.
(D) The art disclosed in patent document 5 can be concluded as using an electrode that is capacitively coupled with plasma, based on the following discussion.
(D-1) Voltage is utilized as the high frequency signal. This means that the high frequency energy is directly converted into voltage, or electric field, and transmitted to plasma. This indicates that the electrode is capacitively coupled with plasma If inductive coupling is used, current must be used as the high frequency. Inductive coupling is performed via an induction magnetic field, but the induction magnetic field is generated not via voltage but via high frequency current.
(D-2) Document 5 discloses a shielding phenomenon via electron motion, but this means that the electrode is capacitively coupled with plasma. The document discloses that the shielding can be solved by a static magnetic field, but such method is only effective when the electrode is capacitively coupled with plasma, since it is impossible to change the skin depth via the static magnetic field. The high frequency induction magnetic field can only be cancelled via a high frequency induction magnetic field, and cannot be cancelled via a static magnetic field. The reason for this is because the magnetic field is a physical quantity capable of being subjected to addition and subtraction, but the static magnetic field (that is, a fixed value) cannot be used to cancel a high frequency induction magnetic field (that is, a variable value). The skin effect of plasma itself is a shielding effect caused via the high frequency magnetic field component of the electromagnetic field, and the skin effect itself is caused by the high frequency induction magnetic field generated in the plasma (which has an opposite polarity with the induction magnetic field applied by the current, so that when added, it operates in the direction to negate the induction magnetic field caused by the current).
(D-3) It is taught that the electrode used in patent document 5 is not an antenna. This only means that the used electrode mainly utilizes near field. In other words, it utilizes either an induction electric field or an induction magnetic field described later.
(D-3-1) Patent document 5 teaches using small patch electrodes having deteriorated efficiency for radiating electromagnetic wave in the drawing. This only means that the used electrodes mainly utilize near field, which is either an induction electric field or an induction magnetic field described later. In the case of an electric field, a large area (large electrostatic capacity) is required to enhance the connection with plasma, whereas in the case of a magnetic field, a line for flowing the current must be formed as a thin long line in parallel with plasma to realize a transformer (inductive coupling). Based on the shape of the electrode, patent document 5 performs capacitive coupling. There is no description nor drawing indicating that the patch electrodes are grounded. As described in (D-3-2), the size of the patch electrodes is shorter than the wavelength of the high frequency, and the voltage and current generated in the patch electrodes fluctuates by the frequency of the applied high frequency, but when observed instantly, a uniform voltage that is not influenced by the wavelength is generated in the whole electrode, and uniform current is flown therethrough. The patch electrode forms both a strong induction electric field and a weak induction magnetic field as near field, wherein the induction electric field has enough area for realizing a strong capacitive coupling with plasma, but the patch electrode does not have sufficient line length capable of realizing a strong transformer-coupling with plasma.
(D-3-2) An example using 13.56 MHz is disclosed, but the wavelength of 13.56 MHz is approximately 22 m, and it cannot be considered that the patch electrode in the drawing resonates with such wavelength (if it resonates, the size of the electrode must be approximately ½ or ¼ of the wavelength, and for example, resonance will not occur if a resonating means is not adopted actively, as disclosed in patent document 4. Further, since it is disclosed that the electrode is not an antenna, it means that the patch electrode is not resonating). Further, there is no plasma processing apparatus for performing predetermined processes for forming semiconductor devices requiring such huge electrodes. This only means that the used electrode mainly utilizes near field, which is either an induction electric field or an induction magnetic field described later. In the case of an electric field, a large area (large electrostatic capacity) is required to increase the connection with plasma, whereas in the case of a magnetic field, a line for flowing the current must be formed as a thin long line in parallel with plasma to realize a transformer (inductive coupling). The shape of the electrode is patch-like, and it has almost no current line for realizing transformer coupling with plasma. Therefore, the patch electrode is considered to be capacitively coupled.
(D-3-3) There is no description nor drawing indicating that the patch electrodes are grounded. Therefore, the current flowing through the patch electrodes must be flown via the plasma to the earth. In other words, the plasma is the load of the patch electrodes, and the current will vary greatly due to the impedance of the generated plasma. As known well, in inductively coupled plasma, current is basically supplied to one end of a line for realizing inductive coupling with plasma, and the other end is earthed. According to this arrangement, current flowing through the line is mainly flown directly to the earth, generating a large current via the earth (the impedance of the load becomes low). Induction magnetic field is generated by the large current, enabling power to be transferred efficiently to the plasma. Of course, the earthed end can be separated from the earth and a capacitor can be inserted thereto, nonetheless, it still offers an arrangement in which large current is generated by devising the electric circuit to generate a strong induction magnetic field by the large current so as to transfer power efficiently to plasma. In other words, since there is no description nor drawing indicating that the patch electrodes are grounded, the patch electrodes must be mainly capacitively coupled with plasma.

Japanese patent application laid-open publication No. 11-135438 (patent document 6) discloses a semiconductor plasma processing apparatus for processing an object to be processed via plasma comprising an evacuated reaction chamber for processing an object to be processed in the interior thereof, an antenna composed of a plurality of linear conductors disposed within the reaction chamber, and an RF high frequency power supply being connected to one end of the plurality of linear conductors, wherein the antenna is composed of at least three linear conductors arranged radially from the center of the antenna at even intervals, wherein each of the linear conductors have one end grounded and the other end connected to the RF high frequency power supply. Further, the surface of the linear conductor of the antenna is insulated. Thus, an inductively coupled plasma processing apparatus capable of generating a uniform, stable and high-density plasma can be obtained. Further, the plasma processing apparatus has an electromagnet for generating a magnetic field in the direction orthogonal to the induction electric field, so that by applying an outer magnetic field, the plasma density can be further improved without changing the applied RF power.

### SUMMARY OF THE INVENTION

Regarding the prior art for generating a right-rotation electric field, no attempts were made to actively create an electric field that rotates in the right direction using an induction magnetic field (near field). Naturally, there has not been developed any art related to causing an ECR phenomenon using the induction electric field actively rotated in the right direction created via the induction magnetic field. Since induction magnetic fields are caused by currents, the apparatus requires a design that is completely contrary to the case where electric fields are used. In other words, the use of induction magnetic fields require active electrodes that generate a strong near field (magnetic field), and the current must be strong, so that the load of electrodes must be of low impedance. In other words, the electrodes used here must be inductively coupled (transformer-coupled) with plasma, which are actively grounded, or grounded via a capacitor or a coil. The induction magnetic field is near field, so that by devising the positional relationship with plasma, large power can be transmitted efficiently to plasma. According to this method, in order to strengthen the inductive coupling, a sufficient line length (coil length) is required to realize coupling with plasma. Since this method utilizes inductive coupling (transformer coupling) of the electrode and plasma, it is possible to use not only antennas (electrodes that radiate electromagnetic wave) but also electrodes (coils) that generate a magnetic field (near field) with only limited ability to radiate electromagnetic wave. The following points are true according to this method.

(A) Phase-controlled current is applied to the electrode.
(B) The electrode has a terminal for applying current, and another terminal for supplying a large current actively from the electrode to the grounded portion. The terminal is either grounded directly or grounded via a capacitor or a coil.
(C) The inductively coupled electric field is shielded via the skin effect, similar to far field. It is impossible to prevent this shielding via a static magnetic field.

In an ICP source, while the high frequency current I circulates the high frequency induction antenna, the current flows via the stray capacitance into the plasma or earth, causing loss. This also causes the induction magnetic field H to have a non-uniform distribution in the circumferential direction, and as a result, a phenomenon in which the uniformity of plasma in the circumferential direction is deteriorated becomes significant. This phenomenon is a wavelength shortening phenomenon that appears as a reflection wave effect or a skin effect which is influenced not only by the permittivity but also by the permeability of the space surrounding the high frequency induction antenna. This phenomenon is a common phenomenon that occurs even in normal high frequency transmission cables such as coaxial cables, but since the high frequency induction antenna is either inductively coupled or capacitively coupled with plasma, the wavelength shortening effect appears more significantly. Further, not only with respect to ICP sources but with respect to common plasma sources such as the ECR plasma source or the parallel plate capacitively coupled plasma source, the traveling wave headed toward the antenna and the interior of the vacuum chamber is superposed with the returning reflected wave, causing standing wave to occur in the antenna radiating high frequency and the space surrounding the same. This is because reflected wave is returned from various areas such as the end of the antenna, the plasma, and the interior of the vacuum chamber having high frequency radiated thereto. The standing wave also relates greatly to the wavelength shortening effect. Under such conditions, in the case of an ICP source, if the frequency of the RF power supply is set to 13.56 Hz having a wavelength as long as approximately 22 m, standing wave with a wavelength shortening effect occurs within the antenna loop when the high frequency induction antenna length exceeds approximately 2.5 m. Therefore, the current distribution within the antenna loop becomes non-uniform, and the plasma density distribution becomes non-uniform.

One problem of the ICP source is that the phase or flowing direction of the high frequency current I flowing through the antenna is periodically reversed, and along therewith, the direction of the induction magnetic field H (the induction electric field E), that is, the direction in which the electrons are driven, is also reversed. In other words, the electrons are repeatedly temporarily stopped every half cycle of the applied high frequency, and accelerated in the opposite direction. In this state, if the avalanche ionization of electrons is insufficient at a certain half cycle of the high frequency, there is a drawback in that plasma having sufficiently high density cannot be obtained when the electrons are temporarily stopped. The reason for this phenomenon is that the generation efficiency of plasma is deteriorated when the electrons are decelerated and temporarily stopped. In general, the ICP source has inferior ignition property of plasma compared to ECR plasma sources and capacitively coupled parallel plate type plasma sources due to the reason mentioned above. Similarly in helicon plasma sources utilizing inductive coupling without performing phase control, the generation efficiency of plasma is deteriorated every half cycle of the high frequency.

As described, ICP sources have been devised in various ways to improve the uniformity of plasma, but there is a drawback in that every attempt to devise the ICP source leads to the complication of structure of the high frequency induction antenna, making it difficult to apply the ICP source to industrial apparatuses. Furthermore, the prior art apparatuses are not intended to significantly improve the ignition property of plasma while maintaining a superior plasma uniformity, so the problem of inferior ignition property has not been solved.

On the other hand, since the ECR plasma source has a short wavelength, a complex electric field distribution is likely to occur within the apparatus, making it difficult to obtain uniform plasma.

Since the wavelength of μ wave (2.45 GHz) is short, the μ wave is propagated within the discharge space via various high-order propagating modes in a large-scale ECR plasma source. Thus, electric field is collectively formed locally at various portions within the plasma discharge space, and high density plasma is generated at those portions. Further, since the μ wave reflected within the plasma apparatus is overlapped with the electric field distribution of incident μ wave propagated via high-order propagating modes and standing wave occurs thereby, electric field distribution within the apparatus may become even more complex. By the above two reasons, it is generally difficult to obtain uniform plasma characteristics throughout a large-scale apparatus. Further, once such complex electric field distribution is generated, it is actually difficult to control the electric field distribution and to change the electric field distribution to a preferable distribution for processing. Such control requires a change in the apparatus structure so as to prevent the occurrence of high-order propagating modes, or to prevent reflected wave reflected from the apparatus from forming a complex electric field distribution. It is almost impossible to achieve via a single apparatus structure a structure most suitable for various discharge conditions. Further, a magnetic field as strong as 875 Gauss is required to generate an ECR discharge via μ wave (2.45 GHz), but there is a drawback in that the power consumed by the coil for generating such magnetic field or the apparatus structure including the yoke becomes extremely large.

As for the magnetic field intensity, the seriousness of the problem is relieved since a relatively weak magnetic field is required for UHF and VHF. However, the problem of standing wave is serious even for UHF and VHF having a relatively long wavelength, which is known to cause problems of non-uniform electric field distribution within the discharge space, and non-uniform plasma density distribution of the generated plasma, which leads to deterioration of the process uniformity. Even now, theoretical and experimental studies are still performed (for example, refer to non-patent document 1: L. Sansonnens et al., Plasma Sources Sci. Technol. 15, 2006, pp 302).

As described, with respect to prior art ICP sources, there were attempts to generate plasma with superior uniformity, but the structure of the antenna became too complex, and the ignition property of plasma was not good. On the other hand, ECR plasma sources have good ignition property, but have drawbacks in that it has deteriorated plasma uniformity due to the high-order propagating modes of electromagnetic wave and the standing wave.

The present invention aims at solving the problems mentioned above, and enables to utilize the ECR discharge phenomenon in a plasma processing apparatus using an ICP source. The present invention enables to optimize the antenna structure through minimum devising, improve the plasma uniformity and significantly improve the ignition property of plasma.

In other words, the object of the present invention is to provide a plasma source having superior ignition property and superior uniformity even when applied to large-scale plasma processing apparatuses.

In order to solve the problems mentioned above, the present invention provides a plasma processing apparatus comprising a vacuum chamber constituting a vacuum processing chamber for storing a sample, a gas inlet for feeding processing gas into the vacuum processing chamber, a high frequency induction antenna for forming an induction electric field within the vacuum processing chamber, a magnetic field coil for forming a magnetic field in the vacuum processing chamber, a plasma generating high frequency power supply for supplying a high frequency current to the high frequency induction antenna, and a power supply for supplying power to the magnetic field coil, for subjecting a sample to plasma processing by supplying the high frequency current from the high frequency power supply to the high frequency induction antenna and turning the gas supplied into the vacuum processing chamber to plasma; wherein the vacuum processing chamber includes a vacuum chamber top member formed of a dielectric body airtightly fixed to an upper portion of the vacuum chamber, and a Faraday shield disposed between the high frequency induction antenna and the vacuum processing chamber; the high frequency induction antenna is divided into n-numbers (integral number of n≧2) of high frequency induction antenna elements, wherein the respective high frequency induction antenna elements are arranged tandemly, having a plurality of sets of tandemly arranged high frequency induction antenna elements, each high frequency induction antenna element of the respective sets of high frequency induction antennas having supplied thereto a high frequency current sequentially delayed by λ (wavelength of the high frequency power supply)/n in order in a fixed direction, so that a rotating induction electric field E that rotates in a right direction with respect to the direction of magnetic field lines of a magnetic field B formed by supplying power to the magnetic field coil is formed via the high frequency current, the rotational frequency of the rotating induction electric field E corresponding to the electron cyclotron frequency via the magnetic field B, and a plurality of sets (the number of sets being a natural number of m≧1) of high frequency induction antennas and the magnetic field are arranged so that a relationship of E×B≠0 is satisfied at an arbitrary portion between the induction electric field E and the magnetic field B to generate plasma, the plasma being used to subject the sample to plasma processing.

The present plasma processing apparatus further comprises an electrode for holding a sample, a bias high frequency power supply for applying high frequency power to the electrode, a Faraday shield high frequency power supply for applying high frequency power to the Faraday shield, an oscillator for supplying high frequency to the bias high frequency power supply and the Faraday shield high frequency power supply, and a phase controller for controlling a phase difference between the bias high frequency power supply and the Faraday shield high frequency power supply. Thereby, the complication of electric circuit for taking out a voltage having a single phase from a power supply having n-number of current outputs having been phase-controlled with respect to n-number of antenna elements can be solved. Further, it becomes possible to prevent the generation of a non-uniform voltage distribution throughout the whole Faraday shield due to the wavelength shortening effect, according to which a uniform self-bias can be applied to the inner side of the vacuum chamber top member. The application of high frequency voltage having the same frequency and controlled voltage phase to a Faraday shield and the object to be processed W adopting the same electrode arrangement as a parallel plate capacitively coupled plasma source realizes an effect of preventing abnormal diffusion of plasma, for example.

According further to the present plasma processing apparatus, the Faraday shield is grounded via a plurality of filters, and by appropriately attaching these filters at intervals of ¼ or smaller of the wavelength of the plasma generating high frequency, an impedance between the Faraday shield and the ground potential is made substantially 0Ω when observed from the frequency of the plasma generating high frequency power supply, whereas the impedance is not substantially 0Ω when observed from the frequency of the Faraday shield high frequency power supply. Based on this arrangement, it becomes possible to prevent the voltage of the plasma generating high frequency to be generated in the Faraday shield, and to enable the high frequency voltage for the Faraday shield to be generated in the Faraday shield. Thereby, the voltage of the Faraday shield can be controlled easily via the output of the Faraday shield high frequency power supply.

According further to the plasma processing apparatus, the frequency of the Faraday shield high frequency power supply and the frequency of the bias high frequency power supply can be set lower than the frequency of the plasma generating high frequency power supply. By setting the frequencies of the Faraday shield high frequency power supply and the bias high frequency power supply as above, it becomes possible to prevent a non-uniform voltage distribution having the same frequency as the plasma generating high frequency power supply to be generated in the Faraday shield, and to create a uniform voltage distribution throughout the whole Faraday shield.

According to the present plasma processing apparatus, the Faraday shield can be formed to cover a whole body of the vacuum processing chamber top member. According to this Faraday shield structure, the Faraday shield disposed between the antenna and plasma shields the capacitive coupling between the antenna and plasma. Thus, it becomes possible to prevent local areas of the top member formed of insulating material (directly below the antenna) from being thinned via sputtering and deteriorated or to prevent particles to be generated via sputtering. Further, since the whole body of the top member formed of insulating material is sputtered via ions so that particles will not be attached thereto, it becomes possible to prevent particles from falling on the surface of the semiconductor wafer.

According to the plasma processing apparatus, a Faraday shield is disposed between the high frequency induction antenna and the vacuum processing chamber, and the voltage thereof can be controlled via the Faraday shield high frequency power supply. Thus, sufficiently strong and uniform electric field can be applied to the whole plasma via capacitive coupling of the Faraday shield at the time of plasma ignition, providing a plasma source having superior ignition property and superior uniformity even in large-scale plasma processing apparatuses.

According to this plasma processing apparatus, the Faraday shield can have a structure composed of a first Faraday shield arranged close to the high frequency induction antenna and a second Faraday shield arranged close to the vacuum processing chamber top member. By grounding the first Faraday shield disposed close to the high frequency induction antenna, it becomes possible to shield the capacitive coupling between the high frequency induction antenna and plasma. According to this arrangement, nearly no high frequency voltage via the plasma generating high frequency is generated to the second Faraday shield arranged close to the vacuum processing chamber top member. Therefore, the second Faraday shield maintains the function of inductively coupling the high frequency induction antenna and plasma via slits while preventing non-uniform voltage of the plasma generating high frequency from being applied to plasma, and enables to apply a uniform high frequency voltage from the Faraday shield high frequency power supply to the vacuum chamber top member.

According to the present plasma processing apparatus, the first Faraday shield is arranged only at the circumference of the high frequency induction antenna. Since the first Faraday shield close to the high frequency induction antenna is formed as a ring-shaped conductor, the first Faraday shield can exert the basic functions of a Faraday shield of shielding the capacitive coupling between the high frequency induction antenna and plasma, preventing revolving current from flowing through the Faraday shield in the direction of the high frequency induction antenna via the multiple slits, and realizing inductive coupling between the high frequency induction antenna and plasma.

Further according to the plasma processing apparatus, the second Faraday shield is formed to cover the whole body of the vacuum processing chamber top member. The second faraday shield can have a function of applying a uniform high frequency voltage to the vacuum chamber top member in addition to the basic function of a Faraday shield, which is to shield the capacitive coupling between the antenna and plasma, but not block the inductive coupling thereof.

The present plasma processing apparatus can further comprise an electrode for holding a sample, a bias high frequency power supply for applying high frequency power to the electrode, a Faraday shield high frequency power supply for applying high frequency power to the second Faraday shield, an oscillator for supplying high frequency to the bias high frequency power supply and the Faraday shield high frequency power supply, and a phase controller for controlling a phase difference between the bias high frequency power supply and the Faraday shield high frequency power supply. According to this plasma processing apparatus, the second Faraday shield arranged close to the vacuum processing chamber top member enables to realize inductive coupling of the high frequency induction antenna and plasma via slits, and the high frequency voltage output from the Faraday shield high frequency power supply subjected to phase control with respect to the bias high frequency power supply can be applied to the vacuum chamber top member, enabling to apply a uniform high frequency voltage to the vacuum chamber top member via a Faraday shield even in an inductively coupled ECR plasma source.

Further according to the plasma processing apparatus, the frequency of the bias high frequency power supply can be set lower than the frequency of the plasma generating high frequency power supply. By determining the frequency of the bias high frequency power supply as above, it becomes possible to prevent a non-uniform voltage distribution of the same frequency as the plasma generating high frequency power supply from being generated in the Faraday shield, and to enable a uniform voltage distribution to be formed throughout the whole Faraday shield.

Further according to the present plasma processing apparatus, the first Faraday shield can be a ring-shaped conductor with slits, the whole circumference of which is grounded. By grounding the first Faraday shield arranged close to the high frequency induction antenna in this manner, it becomes possible to block the capacitive coupling between the high frequency induction antenna and plasma, and the impedance between the first Faraday shield and the ground potential can be made substantially 0Ω when observed from the frequency of the plasma generating high frequency power supply, so as to prevent high frequency voltage from being generated throughout the whole first Faraday shield.

### BRIEF DESCRIPTION OF THE DRAWINGS

FIG. 1 is a vertical cross-sectional view illustrating the outline of the structure of a plasma processing apparatus to which the present invention is applied;

FIG. 2 is an explanatory view showing the method of feeding power to high frequency induction antenna elements according to a first embodiment of the present invention;

FIG. 3A is a view showing the relationship between the phase of currents supplied to the high frequency induction antenna according to the present invention when time t=t1 and the direction of the induction electric field formed thereby;

FIG. 3B is a view showing the relationship between the phase of currents supplied to the high frequency induction antenna at time t=t2 where the phase has been advanced by 90 degrees from the phase of FIG. 3A and the direction of the induction electric field formed thereby;

FIG. 4 is a drawing illustrating the distribution of electric field intensity generated via a prior art high frequency induction antenna;

FIG. 5 is a drawing illustrating the distribution of electric field intensity generated via the high frequency induction antenna of the present invention;

FIG. 6 is an explanatory view illustrating a modified example of the method for feeding power to high frequency induction antenna elements according to the fifth embodiment of the present invention;

FIG. 7 is an explanatory view illustrating a method for feeding power to the high frequency induction antenna elements according to the sixth embodiment of the present invention;

FIG. 8 is an explanatory view illustrating a method for feeding power to the high frequency induction antenna elements according to the seventh embodiment of the present invention;

FIG. 9 is an explanatory view illustrating a method for feeding power to the high frequency induction antenna elements according to the eighth embodiment of the present invention;

FIG. 10 is an explanatory view illustrating a method for feeding power to the high frequency induction antenna elements according to the ninth embodiment of the present invention;

FIG. 11 is an explanatory view illustrating a method for feeding power to the high frequency induction antenna elements according to the tenth embodiment of the present invention;

FIG. 12 is an explanatory view illustrating a method for feeding power to the high frequency induction antenna elements according to the eleventh embodiment of the present invention;

FIG. 13A is an explanatory view illustrating a modified example of the shape of the vacuum chamber top member of the plasma processing apparatus according to the present invention;

FIG. 13B is an explanatory view illustrating another modified example of the shape of the vacuum chamber top member of the plasma processing apparatus according to the present invention;

FIG. 13C is an explanatory view illustrating yet another modified example of the shape of the vacuum chamber top member of the plasma processing apparatus according to the present invention;

FIG. 13D is an explanatory view illustrating yet another modified example of the shape of the vacuum chamber top member of the plasma processing apparatus according to the present invention;

FIG. 13E is an explanatory view illustrating yet another modified example of the shape of the vacuum chamber top member of the plasma processing apparatus according to the present invention;

FIG. 14 is an explanatory view illustrating an example where the shape of the vacuum chamber top member of the plasma processing apparatus according to the second embodiment of the present invention is a hollow semispherical shape;

FIG. 15 is an explanatory view illustrating an example where the shape of the vacuum member top member of the plasma processing apparatus according to the third embodiment of the present invention is a rotated trapezoidal shape;

FIG. 16 is an explanatory view illustrating an example where the shape of the vacuum chamber top member of the plasma processing apparatus according to the fourth embodiment of the present invention is a cylindrical shape with a bottom;

FIG. 17 is an explanatory view illustrating the relationship between the isomagnetics field plane (ECR plane) formed by the present invention and the magnetic field lines;

FIG. 18A is an explanatory view illustrating the relationship between the ECR plane corresponding to the shape of the vacuum chamber top member according to the present invention and the plasma generation region;

FIG. 18B is an explanatory view illustrating the relationship between the ECR plane corresponding to another shape of the vacuum chamber top member according to the present invention and the plasma generation region;

FIG. 18C is an explanatory view illustrating the relationship between the ECR plane corresponding to yet another shape of the vacuum chamber top member according to the present invention and the plasma generation region;

FIG. 18D is an explanatory view illustrating the relationship between the ECR plane corresponding to yet another shape of the vacuum chamber top member according to the present invention and the plasma generation region;

FIG. 18E is an explanatory view illustrating the relationship between the ECR plane corresponding to yet another shape of the vacuum reactor top member according to the present invention and the plasma generation region;

FIG. 19 is an explanatory view illustrating the method for feeding power to multiple sets of high frequency induction antenna elements according to the twelfth embodiment of the present invention;

FIG. 20 is an explanatory view illustrating the method for feeding power to multiple sets of high frequency induction antenna elements according to the thirteenth embodiment of the present invention;

FIG. 21 is an explanatory view illustrating the method for feeding power to multiple sets of high frequency induction antenna elements according to the fourteenth embodiment of the present invention;

FIG. 22 is an explanatory view illustrating the method for feeding power to multiple sets of high frequency induction antenna elements according to the fifteenth embodiment of the present invention;

FIG. 23A is an explanatory view illustrating the arrangement of the multiple sets of high frequency induction antenna elements corresponding to the modified example of the shape of the vacuum chamber top member according to the plasma processing apparatus of the present invention;

FIG. 23B is an explanatory view illustrating the arrangement of the multiple sets of high frequency induction antenna elements corresponding to another modified example of the shape of the vacuum chamber top member according to the plasma processing apparatus of the present invention;

FIG. 23C is an explanatory view illustrating the arrangement of the multiple sets of high frequency induction antenna elements corresponding to yet another modified example of the shape of the vacuum chamber top member according to the plasma processing apparatus of the present invention;

FIG. 23D is an explanatory view illustrating the arrangement of the multiple sets of high frequency induction antenna elements corresponding to yet another modified example of the shape of the vacuum chamber top member according to the plasma processing apparatus of the present invention;

FIG. 23E is an explanatory view illustrating the arrangement of the multiple sets of high frequency induction antenna elements corresponding to yet another modified example of the shape of the vacuum chamber top member according to the plasma processing apparatus of the present invention;

FIG. 23F is an explanatory view illustrating the arrangement of the multiple sets of high frequency induction antenna elements corresponding to yet another modified example of the shape of the vacuum chamber top member according to the plasma processing apparatus of the present invention;

FIG. 23G is an explanatory view illustrating the arrangement of the multiple sets of high frequency induction antenna elements corresponding to yet another modified example of the shape of the vacuum chamber top member according to the plasma processing apparatus of the present invention;

FIG. 24 is an explanatory view showing the method for feeding power to the multiple sets of high frequency induction antenna elements arranged in a rectangle according to the sixteenth embodiment of the present invention;

FIG. 25 is an explanatory view showing the method for feeding power to the multiple sets of high frequency induction antenna elements arranged in a rectangle according to the seventeenth embodiment of the present invention;

FIG. 26 is an explanatory view showing the standing wave distribution of the current and the voltage generated in an antenna element when the state of the standing wave within the antenna element cannot be ignored;

FIG. 27 is a view illustrating the method for applying a bias high frequency to the Faraday shield according to the eighteenth embodiment of the present invention;

FIG. 28 is a view showing the state in which filters are inserted to multiple locations within the Faraday shield illustrated in FIG. 27;

FIG. 29 is an explanatory view illustrating another method for applying a bias high frequency to the Faraday shield according to a nineteenth embodiment of the present invention; and

FIG. 30 is a view illustrating the relationship between the frequency f of the electromagnetic wave and the cutoff density nc.

### DETAILED DESCRIPTION OF THE PREFERRED EMBODIMENTS

The application of the plasma processing apparatus according to the present invention is not restricted to the field of manufacturing semiconductor devices, and the present plasma processing apparatus can be applied to various fields of plasma processing, such as the fabrication of liquid crystal displays, the deposition of films of various materials, and surface treatments. In the present description, preferred embodiments of the present invention are illustrated by taking a plasma etching apparatus for manufacturing semiconductor devices as an example.

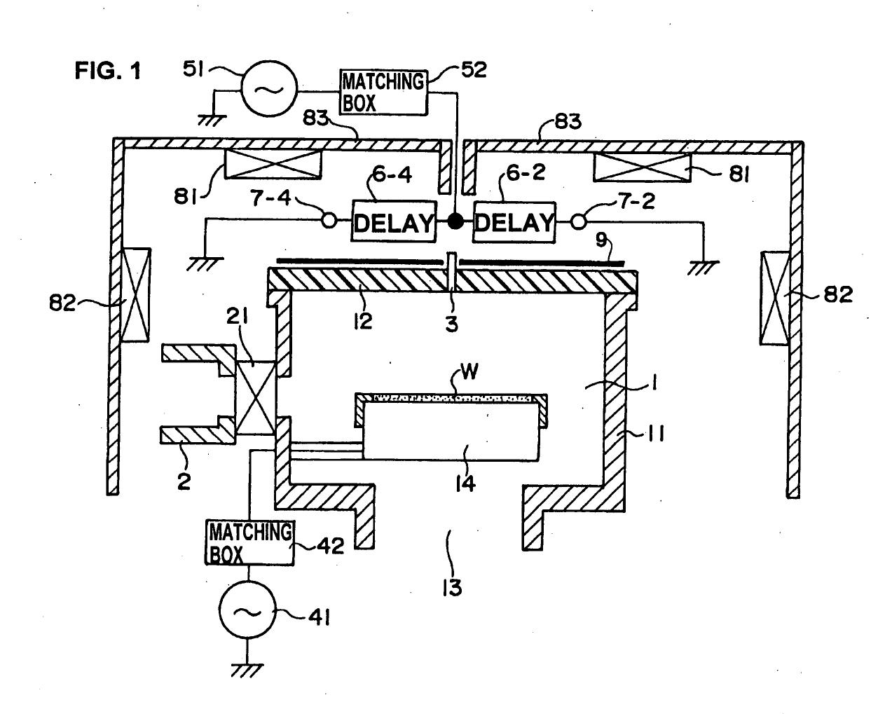

The outline of the structure of the plasma processing apparatus to which the present invention is applied will be described with reference to FIG. 1. A high frequency inductively coupled plasma (ICP) processing apparatus comprises a cylindrical vacuum chamber 11 including a vacuum processing chamber 1 having the interior thereof maintained to vacuum, a top member 12 of the vacuum processing chamber formed of an insulating material for introducing an electric field generated via high frequency into the vacuum processing chamber, an evacuation means 13 connected for example to a vacuum pump for maintaining the interior of the vacuum processing chamber 1 to vacuum, an electrode (sample stage) 14 on which an object to be processed (a semiconductor wafer) W is placed, a transfer system 2 including a gate valve 21 for transferring the semiconductor wafer W being the object to be processed into and out of the vacuum processing chamber, a gas inlet 3 for introducing processing gas, a bias high frequency power supply 41 for applying bias voltage to the semiconductor wafer W, a bias matching box 42, a plasma generating high frequency power supply 51, a plasma generating matching box 52, a plurality of delay means 6-2, 6-3 (not shown) and 6-4, high frequency induction antenna elements 7-1 (not shown), 7-2, 7-3 (not shown) and 7-4 divided into multiple parts and arranged tandemly on a circumference constituting a high frequency induction antenna 7 arranged on the upper area of the circumference of the vacuum processing chamber 1, an electromagnet composed of an upper magnetic coil 81 and a lower magnetic coil 82 for applying a magnetic field, a yoke 83 formed of a magnetic body for controlling the distribution of the magnetic field, a Faraday shield 9 for controlling the capacitive coupling between the high frequency induction antenna elements 7-1 (not shown), 7-2, 7-3 (not shown) and 7-4 and plasma, and a magnetic field coil power supply not shown for supplying power to the electromagnet.

The vacuum chamber 11 is, for example, a vacuum chamber formed of aluminum having alumite-treated surface or of stainless steel, which is electrically grounded. Further, surface treatments can also be performed using materials other than alumite, such as substances having high resistance to plasma (such as yttria: Y₂O₃). The vacuum processing chamber 1 comprises an evacuation means 13, and a transfer system 2 including a gate valve 21 for transferring the semiconductor wafer W being the object to be processed into and out of the chamber. In the vacuum processing chamber 1, an electrode 14 for placing the semiconductor wafer W concentrically with the cylindrical vacuum chamber 11 is disposed concentrically with the cylindrical vacuum chamber 11. Through the transfer system 2, the wafer W carried into the vacuum processing chamber is carried onto the electrode 14 and is held on the electrode 14. A bias high frequency power supply 41 is connected via a bias matching box 42 to the electrode 14 with the aim to control the energy of ions being incident on the semiconductor wafer W during plasma processing. Gas used for the etching process is fed into the vacuum processing chamber 1 through the gas inlet 3.

On the other hand, high frequency induction antenna elements 7-1 (not shown), 7-2, 7-3 (not shown) and 7-4 are placed at a position opposed to the semiconductor wafer W at an atmospheric side of the vacuum chamber top member 12 formed of insulating material, such as plate-shaped quartz or alumina ceramics. The high frequency induction antenna elements 7-1 through 7-4 are disposed concentrically with the center thereof corresponding to the center of the semiconductor wafer W. Although not shown clearly in FIG. 1, the high frequency induction antenna elements 7-1 through 7-4 are composed of multiple antenna elements having the same shape. The power feed ends A of the multiple antenna elements are connected via the plasma generating matching box 52 to the plasma generating high frequency power supply 51, and the grounded ends B are connected in the same manner to ground potential.

Delay means 6-2, 6-3 (not shown) and 6-4 for delaying the phase of currents flowing in the respective high frequency induction antenna elements 7-1 through 7-4 are disposed between the high frequency induction antenna elements 7-1 through 7-4 and the plasma generating matching box 52.

A refrigerant flow channel not shown for cooling is formed on the top member 12 of the vacuum chamber, and cooling can be performed by supplying fluids such as water, Fluorinert, air or nitrogen to the refrigerant flow channel. The antenna, the vacuum chamber 11 and the wafer stage 14 are also subjected to cooling and temperature control.

### Embodiment 1

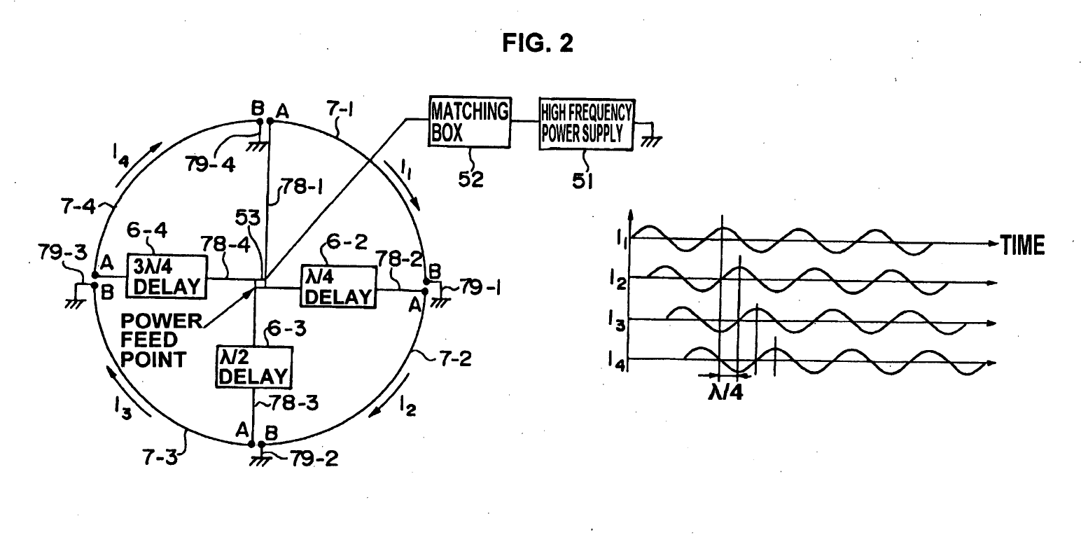

With reference to FIG. 2, a first embodiment of the plasma processing apparatus according to the present invention will be described. According to this embodiment, as shown in the left side of FIG. 2 showing a top view of FIG. 1, the high frequency induction antenna 7 is divided into high frequency induction antenna elements 7-1 through 7-4, formed by dividing the antenna into n=4 (n being an integer of n 2) parts on a single circumference. The power feed ends A or the grounded ends B of the respective high frequency induction antenna elements 7-1, 7-2, 7-3 and 7-4 are separated by angle 360°/4 (360°/n) in the clockwise direction, and high frequency current is supplied from the plasma generating high frequency power supply 51 via the plasma generating matching box 52 through the feeding point 53 via the respective power feed ends A to the respective high frequency induction antenna elements 7-1, 7-2, 7-3 and 7-4. In the present embodiment, the respective high frequency induction antenna elements 7-1 through 7-4 have grounded ends B disposed at a distance of approximately λ/4 (λ/n) from the power feed ends A in a right rotation of the same circumference. It is not necessary for the high frequency induction antenna elements 7-1 through 7-4 to have a length of λ/4 (λ/n), but it is preferable that the length is equal to or smaller than λ/4 (λ/n) of the generated standing wave. Furthermore, depending on the arrangement of the antenna, the length of the respective high frequency induction antenna elements should be equal to or smaller than λ/2. A λ/4 delay circuit 6-2, a λ/2 delay circuit 6-3 and a 3λ/4 delay circuit 6-4 are respectively inserted between the power feed point 53 and the power feed end A of the high frequency induction antenna elements 7-2, 7-3 and 7-4. Thereby, the currents I₁, I₂, I₃ and I₄ flowing through the respective induction antenna elements 7-1 through 7-4 have phases respectively delayed by λ/4 (λ/n) in order as shown in the graph on the right side of FIG. 2. The electrons in the plasma driven by current I₁ is sequentially driven by current I₂. Further, the electrons in the plasma driven by current I₃ is sequentially driven by current I4.

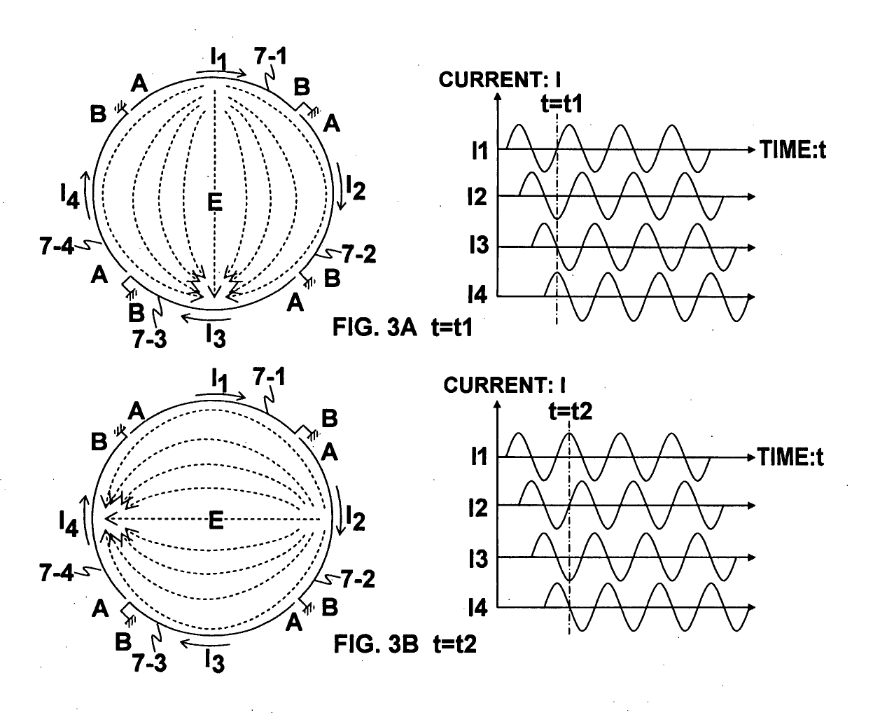

With reference to FIG. 3, we will now describe how the electrons in the plasma are driven using the high frequency induction antenna shown in FIG. 2. In FIG. 3, the arrangement of the power feed ends A and the grounded ends B of the high frequency induction antenna elements 7-1, 7-2, 7-3 and 7-4 is the same as that illustrated in FIG. 2. Further, currents I1 through I4 flown through the respective induction antenna elements are all directed from the power feed ends A toward the grounded ends B. The phases of currents I1 through I4 flowing through the respective high frequency induction antenna elements are respectively displaced by 90°, similar to FIG. 2. The phases are displaced by 90° so as to allocate a single cycle)(360° of the high frequency current to four high frequency induction antenna elements, according to which the relationship satisfies 360°/4=90°. Here, the current I and the induction electric field E are associated via Maxwell's equations shown in expressions (1) and (2) using the induction magnetic field H. In the following expressions (1) and (2), E, H and I represent vectors of all the electric field, the magnetic field and the current in the plasma via the high frequency induction antenna, μ represents permeability, and ∈ represents permittivity.

$$\begin{matrix}[ Expression 1 ] & \\ ∇ \times E = - μ \frac{\partial H}{\partial t} & ( 1 ) \\ [ Expression 2 ] & \\ ∇ \times H = ɛ \frac{\partial E}{\partial t} + I & ( 2 )\end{matrix}$$

The right side of FIG. 3A illustrates the relationship between phases of the currents. The direction of the induction electric field E in the area surrounded by the high frequency induction antenna at a certain point of time (t=t1) in the right side of FIG. 3A is shown by dotted lines and arrows in the left side of FIG. 3A. As can be seen from the drawing, the distribution of the induction electric field E is axisymmetric with the plane on which the antenna is arranged, that is, with the plane defined by the antenna. FIG. 3B shows the direction of the induction electric field E when the phase of the current is advanced by 90° (t=t2) compared to FIG. 3A. The direction of the induction electric field E is rotated for 90° in the clockwise direction. Based on FIG. 3, it can be recognized that the high frequency induction antenna according to the present invention creates an induction electric field E that rotates in the right direction, that is, in the clockwise direction, with time. When electrons exist in the induction electric field E rotating in the right direction, the electrons are also driven by the induction electric field E to rotate in the right direction. In that case, the rotation cycle of electrons correspond to the frequency of the high frequency current. However, it is possible to create an induction electric field E having a rotation cycle that differs from the frequency of the high frequency current through engineering approach, and in that state, the electrons are rotated not via the same cycle as the frequency of the high frequency current but via the same cycle as the rotation cycle of the induction electric field E. As described, the electrons are driven by the induction electric field E, similar to normal ICP sources. However, the present invention differs from normal ICP sources or helicon plasma sources in that the electrons are driven in a fixed direction (which according to the present drawing is the right direction) regardless of the phase of current I of the high frequency induction antenna, and in that the rotation will not be stopped momentarily.

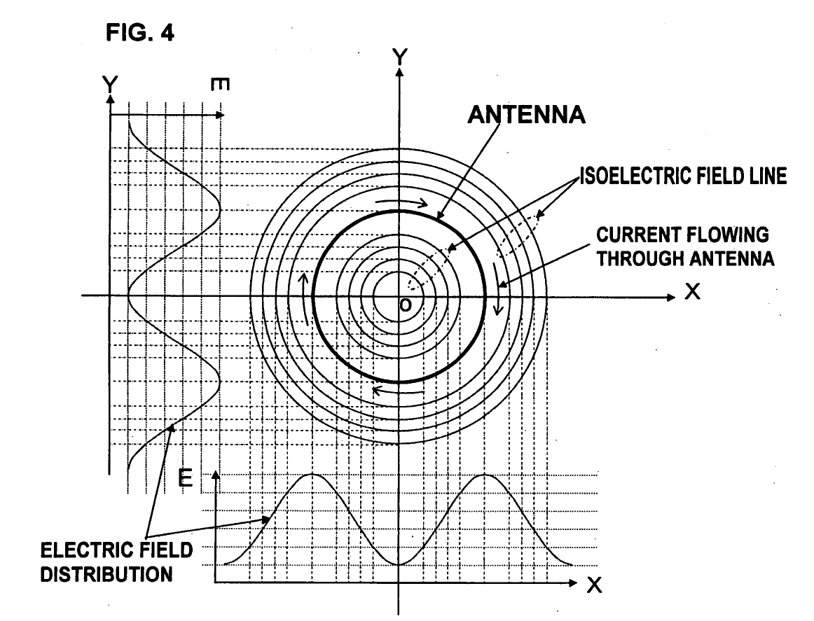

Next, we will describe the properties of the induction electric field E formed in the plasma by the high frequency induction antenna according to the present invention. In the description, we will describe the properties of the induction electric field E, but as shown in expression (1), the induction electric field E and the induction magnetic field H have mutually convertible physical quantities, and they are equivalent. At first, FIG. 4 shows a typical distribution of the induction electric field E created by the prior art ICP source. According to the prior art ICP source, currents of the same phase are flown through the antenna regardless of whether the antenna constitutes a complete circle or the antenna is divided into multiple elements, so that the induction electric field E created by the antenna is uniform in the circumferential direction. In other words, as shown in FIG. 4, a donut-shaped electric field distribution is created in which the maximum value of the induction electric field E appears directly below the antenna and the electric field is attenuated toward both the center and the circumference of the antenna. This distribution is point-symmetric with respect to center point O in the X-Y plane. Theoretically, the induction electric field E at the center point O of the antenna is E=0. The donut-shaped electric field distribution is rotated both in the right and left directions corresponding to the direction of the current (that changes every half cycle). The rotational direction of the induction electric field E is reversed when the current becomes zero, and at that time, the induction electric field E becomes E=0 temporarily at all areas. Such an induction electric field E has already been measured as an induction magnetic field H, and confirmed (refer for example to non-patent document 2: J. Hoopwood et al., J. Vac. Sci. Technol., A11, 1993, pp 147).

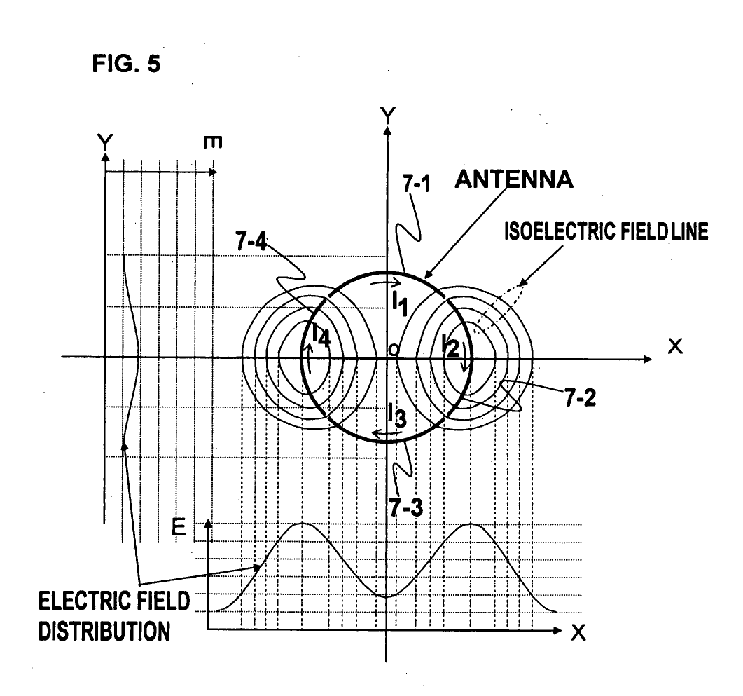

Next, we will describe the induction electric field E created by the antenna according to the present invention. At first, we will consider the same current status as FIG. 3A. That is, a positive peak current flows in I₄, and an opposite peak current flows in I₂. In contrast, I₁ and I₃ are small. In this state, the maximum value of the induction electric field E appears below the antenna element 7-4 through which I₄ flows and below the antenna element 7-2 through which I₂ flows. No strong induction electric field E appears below antenna elements 7-1 and 7-3 through which very little current flows. FIG. 5 illustrates a typical example of this state. In the drawing, two peaks appear on the axis of the X-Y plane. As can be seen from FIG. 5, the induction electric field E according to the present invention has two high peaks on the circumference of the antenna, and is axisymmetric with respect to the X-Y plane (in the drawing, it is axisymmetric with the Y axis). According to the distribution, a gentle peak appears on the Y axis. The peak height of the gentle distribution is low, and the peak appears on the central coordinate O. In other words, the induction electric field at center point O of the antenna is not E=0. As described, according to the arrangement of FIG. 2 of the present invention, the created induction electric field E is completely different from that created by the prior art ICP sources or helicon plasma sources, and further, the electric field E rotates in a fixed direction (right direction in the drawing) regardless of the phase of the current I of the high frequency induction antenna. Further, as can be seen in FIG. 3, there is no moment where the currents I flowing in all the high frequency induction antenna elements simultaneously become I=0. One of the characteristics of the present invention is that there is no moment where the rotating induction electric field E becomes E=0.

According to the present invention, such an induction electric field distribution having a local peak is generated, but the uniformity of plasma is not deteriorated thereby. First, the induction electric field distribution on the X axis of FIG. 5 is determined by the induction magnetic field distribution generated by the antenna. In other words, when the same amount of current flows, the induction electric field distribution on the axis of FIG. 4 and the induction electric field distribution on the axis of FIG. 5 are equal in the sense that they are induction electric fields having a symmetric shape with two peaks having the center point O set as the center. Further, since the induction electric field of the present invention rotates via the same frequency as the high frequency current flowing through the antenna, so that by averaging the electric field by a single cycle of the high frequency current, a point-symmetric induction electric field distribution with respect to the center point O in the X-Y plane is created. In other words, a completely different induction electric field distribution is created according to the present invention, but the superior features of the prior art ICP source are still maintained, which are that the induction electric field distribution is determined by the structure of the antenna, and that a point-symmetric plasma uniform in the circumferential direction is generated.

Now, by utilizing upper and lower magnetic field coils 81 and 82 and the yoke 83 illustrated in FIG. 1, it becomes possible to apply a magnetic field B having a magnetic field component perpendicular with respect to the rotation plane of the induction electric field E. According to the present invention, there are two conditions that must be satisfied by the magnetic field B. The first condition is to apply a magnetic field B so that the rotational direction of the induction electric field E is constantly in the right direction with respect to the direction of the magnetic field lines of the magnetic field B. For example, according to the arrangement of FIG. 2, the induction electric field E is rotated in the clockwise direction, that is, in the right direction, with respect to the paper plane. In that case, the direction of the magnetic field lines requires a component that is directed from the front side of the paper plane toward the rear side thereof. Thereby, the rotational direction of the induction electric field E corresponds to the rotational direction of the Lamar motion of electrons. The first condition can also be defined as applying a magnetic field B in which the rotational direction of the induction electric field E corresponds to the rotational direction of the Larmor motion of electrons.

The remaining condition is to apply a magnetic field B satisfying E×B≠0 with respect to the induction electric field E. However, this condition to satisfy E×B≠0 must be realized at some area in the space for generating plasma but not in the whole space for generating plasma. There are many methods for applying magnetic fields, but unless a magnetic field having a locally complex structure is used, the present condition of “E'B≠0” is included in the first condition mentioned earlier. According to this condition of “E×B≠0”, the electrons are driven in a rotational motion so-called Larmor motion centered around the magnetic field lines (guiding center). This Larmor motion is not a rotational motion caused by the aforementioned rotating induction electric field, but is a motion so-called electron cyclotron motion. The rotational frequency thereof is called an electron cyclotron frequency ωc, which can be shown by the following expression (3). According to the following expression (3), q represents the elementary charge of electrons, B represents the magnetic field intensity, and me represents the electron mass. The characteristics of the present electron cyclotron motion is that the frequency thereof is determined only by the magnetic field intensity.

$$\begin{matrix}[ Expression 3 ] & \\ {ω}_{c} = \frac{qB}{{m}_{e}} & ( 3 )\end{matrix}$$

Now, when the rotational frequency f of the rotating induction electric field E is set to correspond to the cyclotron frequency ωc so that 2πf=ωc, electron cyclotron resonance occurs, and the high frequency power flown through the high frequency induction antenna is resonantly absorbed by the electrons, by which high density plasma can be generated. However, this condition that “the rotational frequency f of the induction electric field E is set to correspond to the cyclotron frequency ωc” must be realized at some area within the space for generating plasma but not in the whole space for generating plasma. This ECR generating condition can be represented by the following expression (4), as mentioned earlier.

[Expression 4]

2πf=ω_{c} (4)

The magnetic field B applied here can be either a static magnetic field or a variable magnetic field. However, in the case of a variable magnetic field, the variable frequency fB must satisfy a relationship of 2πfB<<ωc with the rotational frequency of the Larmor motion (electron cyclotron frequency ωc). What is meant by this relationship is that the change of the variable magnetic field is sufficiently small, and can be regarded as a static magnetic field when observed from a single cycle of electrons performing electron cyclotron motion.

As described, the plasma generating ability of electrons can be improved dramatically using a plasma heating method called electron cyclotron (ECR) heating. However, in order to achieve the desired plasma characteristics in practical industrial application, it is preferable to optimize the antenna structure so as to control the intensity of the induction electric field E and the distribution thereof, and to variably control the intensity distribution of the magnetic field B, in order to form a space satisfying the conditions of the magnetic field B and the frequency only at necessary areas, and to control the generation of plasma and the diffusion thereof. FIG. 1 illustrates an embodiment considering the above features.

Furthermore, the method for enabling ECR discharge using an ICP source according to the present invention does not depend on the frequency of the high frequency or the intensity of the magnetic field being used, and can be applied anytime as long as the conditions mentioned earlier are satisfied. Of course, regarding technological applications, there are restrictions to the usable frequency and magnetic field intensity due to practical restrictions such as the size of the reactor for generating plasma. For example, if the radius rL of the Larmor motion of electrons shown in the following expression is greater than the reactor for confining plasma, ECR phenomenon will not occur since the electrons collide against the wall of the reactor without performing cyclic motion. In expression (5), ν is the velocity of electrons in the direction horizontal to the electric field shown in FIG. 3.

$$\begin{matrix}[ Expression 5 ] & \\ rL = \frac{v}{{ω}_{c}} & ( 5 )\end{matrix}$$

In this case, of course, the high frequency being used must be increased and the magnetic field intensity must also be increased so that the ECR phenomenon occurs. However, the frequency and the magnetic field intensity should be selected freely according to the object of the process, and the principle of the present invention will not be detracted in any way.

We will organize the necessary and sufficient conditions of the principle for enabling ECR discharge using an ICP source according to the present invention into following four points. The first point is to form a distribution of the induction electric field E that rotates constantly in the right direction with respect to the direction of the magnetic field lines of the magnetic field B applied to the space for generating plasma. The second point is to apply a magnetic field B that satisfies E×B≠0 with respect to the distribution of the induction electric field E that rotates in the right direction with respect to the direction of the magnetic field lines of the magnetic field B. The third point is to have the rotational frequency f of the rotating induction electric field E correspond with the electron cyclotron frequency ωc of the magnetic field B. The fourth point is that when observed from a single cycle of electrons performing electron cyclotron motion, the change of the magnetic field B is so small that the magnetic field can be regarded as a static magnetic field. FIG. 1 illustrates an embodiment satisfying all four points listed above, but even if the embodiment of FIG. 1 is modified, ECR discharge using an ICP source is still enabled as long as the above-listed necessary and sufficient conditions are satisfied. In other words, regardless of how the configuration of the apparatus of FIG. 1 is modified, the apparatus still constitutes an embodiment of the present invention as long as the above necessary and sufficient conditions are satisfied. Such modification is merely a matter of engineering design, and does not alter the physical principle taught in the present invention. We will now describe the modified examples of FIG. 1.

In FIG. 1, the top member 12 of the vacuum chamber is composed of a flat plate-like insulating material, and a high frequency induction antenna 7 is arranged above the top member. According to this arrangement, an induction electric field E distribution that constantly rotates in the right direction with respect to the direction of the magnetic field lines of the magnetic field B is formed in the space for forming plasma, that is, in the space sandwiched between the top member 12 of the vacuum chamber and object to be processed W. This constitutes the first point of the above-mentioned necessary and sufficient conditions. Therefore, the top member 12 of the vacuum chamber being a flat plate-like insulating member and the high frequency induction antenna 7 being formed above the top member 12 of the vacuum chamber are not necessary conditions according to the present invention. For example, the vacuum chamber top member 12 can be a rotated trapezoidal shape, a hollow hemispherical shape or dome shape, or a cylindrical shape with a bottom. Further, the high frequency induction antenna can be positioned at any location with respect to the vacuum chamber top member. Based on the principles of the present invention, any shape of the vacuum chamber top member 12 and the position of the antenna with respect to the vacuum chamber top member that satisfies the above-mentioned necessary and sufficient conditions constitutes an embodiment of the present invention.

However, in industrial application, the shape of the vacuum chamber top member and the position of the antenna with respect to the vacuum chamber top member have important meanings, since uniform processing is required to be performed within the plane of the object to be processed W. In other words, the components of the gas species constituting the plasma, such as the ions and radicals used for processing the surface of the object to be processed W, must be distributed uniformly.

Plasma is generated by the process gas being dissociated, excited and ionized by high energy electrons. The radicals and ions generated at this time have strong electron energy dependency, and not only the generated quantity but also the generation distribution of radicals and ions differ. Thus, it is practically impossible to generate radicals and ions having the completely same distribution. Further, the generated radicals and ions spread via diffusion, but the diffusion coefficients differ among various radicals and ions. Especially, the diffusion coefficient of ions is generally greater by a digit than the diffusion coefficient of neutral radicals. In other words, it is actually impossible to simultaneously realize a uniform distribution of radicals and ions over the object to be processed W using diffusion. Furthermore, if the process gas is composed of molecules or if the plasma is generated by mixing various gases, a variety of species of radicals and ions are generated, so that it is even more impossible to realize a uniform distribution of all radicals and ions. However, what is important in realizing a uniform process is the specific gas species that advance the process in which plasma is applied. For example, if the reaction is advanced mainly by a specific radical, it is important that the distribution of this specific radicals is made uniform. In contrast, if the reaction is advanced mainly by ion sputtering, it is important that the distribution of this specific ions is made uniform. Further, there are cases where the reaction is progressed by the competition of radicals and ions. In order to cope with such various processes, it is desirable that the distribution of the generated plasma and the diffusion thereof is controlled, so that respective processes are progressed with a more desirable uniformity.

There are two types of measures to cope with such demands according to the present invention. According to the present invention, the energy of electrons for generating plasma is determined by E×B, or more simply put, by the induction electric field E and the magnetic field. The first measure relates to the induction electric field E, wherein the shape of the vacuum chamber top member 12 formed of an insulating body and the position of the antenna with respect thereto are optimized per process. As described earlier, the generation distribution of plasma is determined by the structure of the antenna according to the present invention, similar to normal ICP sources. This is because the strongest induction electric field E is formed near the antenna. Further, the distribution of generated radicals and ions can be controlled by the expansion of space defined by the vacuum chamber top member, the object to be processed and the vacuum chamber. This is strongly related with the magnetic field B in the second measure, but for sake of explanation, we will not consider the magnetic field at this time.

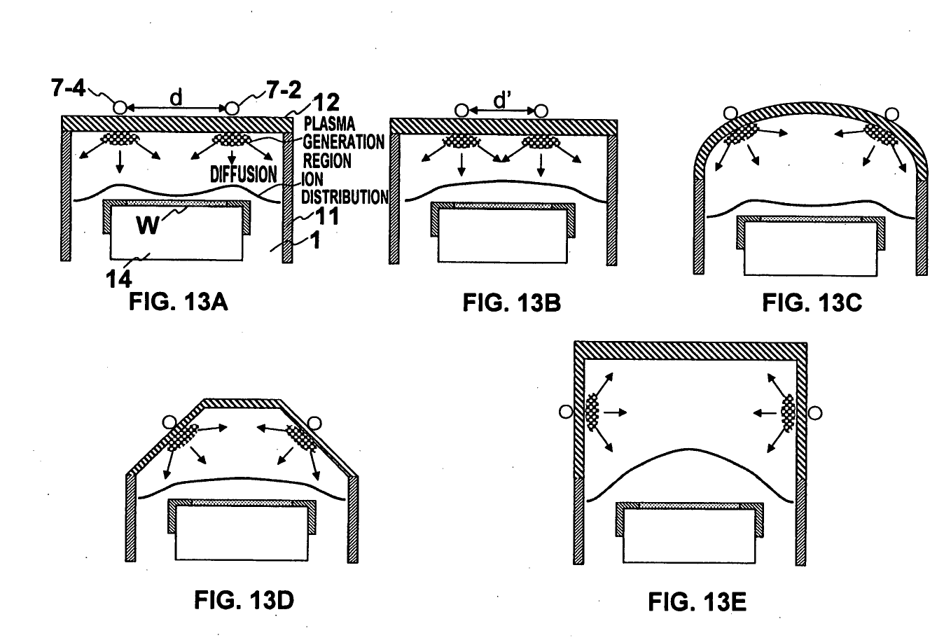

FIG. 13 shows the shapes of distribution above the object to be processed W with respect to the four types of shapes of the vacuum chamber top member 12 formed of an insulating member and the antenna positions. For sake of explanation, it is assumed that this distribution shows the ion distribution. FIG. 13A illustrates a case where the vacuum chamber top member 12 is a flat plate-like shape. The high frequency induction antenna elements 7 are disposed above the vacuum chamber top member 12 formed of insulating member, and an ion (plasma) generation space P appears immediately below the antenna. The ions generated at this time are diffused and spread within the space defined by the vacuum chamber top member 12 and the vacuum chamber 11. Qualitatively described, the direction of diffusion is mainly downward. It is assumed that an M-shaped ion distribution is formed above the object to be processed W according to this diffusion. Now, it is assumed that the distance d between the antennas is reduced, as shown in d′ of FIG. 13B. By such change in antenna position, the diffusion of ions is further directed toward the center direction of the object to be processed W. Therefore, the ion distribution above the object to be processed W can be made further center high. Further, although not shown, by widening the distance between the antennas, the M-shaped distribution of ions can be emphasized. In other words, the change of antenna structure is extremely effective in controlling the ion distribution. However, the simple change of antenna structure causes the distribution of ions and radicals other than the specific ions considered here to be varied in the same manner. This is because the spreading of plasma generating region with respect to the antenna is not varied so much, and the space formed by the vacuum chamber top member 12 formed of insulating material and the vacuum chamber 11 is not changed.

Such distribution control is made possible by varying the shape of the vacuum chamber top member 12 formed of insulating material. FIGS. 13C, 13D and 13E show the patterns of the distribution of ions when the shape of the vacuum chamber top member is changed to a hollow semispherical or dome-shape, a rotated trapezoidal shape with a hollow space formed in the interior thereof (rotational trapezoidal shape), and a cylinder with a bottom. What can be recognized from these views is that along with the change in the shape of the vacuum chamber top member 12 composed of insulating material from that shown in FIG. 13A to those shown in FIGS. 13C, 13D and 13E, the dispersion of ions toward the center is increased. Therefore, along with the change of shape from FIG. 13A to FIGS. 13C, 13D and 13E, the ion distribution above the object to be processed W is made further center-high.

In the drawing, FIGS. 13B and 13D show a similar ion distribution above the object to be processed W. This is made possible by designing the structure of the actual apparatus in an appropriate manner. However, the change of design from FIG. 13A to 13B and that from FIG. 13A to 13 has a definite difference. That is, the volume of the space defined by the vacuum chamber top member 12 and the vacuum chamber 11 and the surface area thereof differ.

At first, the probability of ions being eliminated within the space is extremely small, and the elimination is mainly caused by the release of charge at the surface of the wall. In order for the ions to be eliminated in space, for example, an extremely rare reaction is required in which an electron collides against two electrons at the same time (triple collision). Further, the collision of ions on the wall has a limitation in that the ions must be equivalent with electrons (quasi-neutral conditions of plasma). However, radicals are neutral excitation species, and they lose their active energy easily by colliding against single electrons or other molecules. The opposite is also true. Further, radicals also collide against the wall and lose their excitation energy, but the inflow thereof is unrelated with the quasi-neutral conditions of plasma, and merely depends on the diffusion quantity to the wall. Of course, as mentioned earlier, the diffusion coefficient of ions and radicals differ greatly. That is, by varying the volume and the surface area of the space defined by the vacuum chamber top member 12 formed of insulating material and the vacuum chamber 11, the generation region, dispersion and level of elimination of radicals with respect to ions can be changed further dramatically. As described, compared to the change of design from FIG. 13A to FIG. 13B, it can be understood that the change of design from FIG. 13A to FIG. 13D enables to control the distribution of ions and radicals more dynamically.

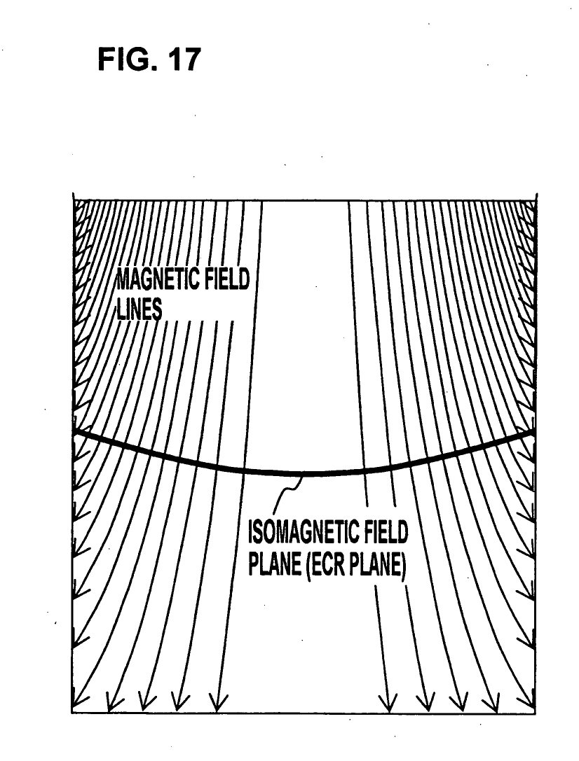

The second measure is related to the magnetic field B, wherein the generation and diffusion of plasma is optimized by variably controlling the shape of the vacuum chamber top member 12 formed of insulating material and the magnetic field distribution with respect thereto. According to the embodiment shown in FIG. 1, the magnetic field intensity and the distribution thereof is controlled by the currents flown through the upper and lower magnetic field coils 81 and 82 and the shape of the yoke 83. At this time, for example, a magnetic field as shown in FIG. 17 can be generated. The characteristic of the magnetic field is that the direction of the magnetic field lines is directed downward. Based on the direction of the magnetic field lines and the direction of the electric field shown in FIG. 3, the rotational direction of the electric field shown in FIG. 3 and the Larmor motion of electrons are made to rotate in the same right direction with respect to the direction of the magnetic field lines. In other words, the present magnetic field is an example in which the aforementioned first and second necessary and sufficient conditions are satisfied.

An isomagnetic field plane is formed on a plane perpendicular to the magnetic field lines. There are unlimited numbers of isomagnetic field planes, and one example of which is shown in FIG. 17. At this time, assuming that the rotation cycle of the induction electric field distribution rotating in a fixed direction is 100 MHz, based on expression (3), the isomagnetic field plane of approximately 35.7 Gauss is the magnetic field intensity plane causing ECR discharge. This plane is called the ECR plane. In this example, the ECR plane is convexed downward, but it can also be planar or convexed upward. In the present invention, it is indispensible that the ECR plane is created in the plasma generating region, but the shape of the ECR plane can be arbitrary. The ECR plane can be moved upward or downward by varying the current flown through the upper and lower magnetic field coils 81 and 82, but the shape of the plane can be convexed further downward, can be made planar, or can be convexed upward.

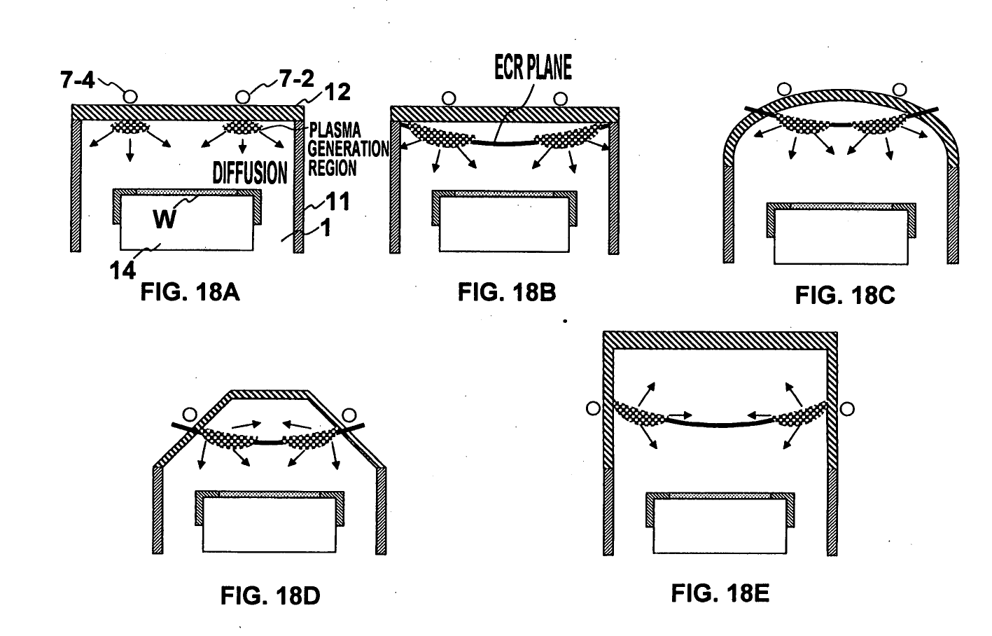

Next, with reference to FIG. 18, we will describe the effect realized by the combination of the variations of the ECR plane and the shapes of the vacuum chamber top member. FIG. 18A is completely same as FIG. 13A, showing the pattern of the generation region of plasma (region shown by the checked pattern) and the direction of diffusion thereof when there is no magnetic field. An example where an ECR plane is formed with respect to FIG. 13A is shown in FIG. 18B. What is important is that (1) the plasma generation region by ECR exists along the ECR plane. From the drawing, it can be understood qualitatively that the generation regions of ions and radicals in the plasma differ between cases where there is no magnetic field and where an ECR plane is formed. Next, (2) the intensity of discharge is increased in response to the size of the induction electric field E when there is no magnetic field, but in ECR discharge, the intensity of discharge is increased in response to the size of E×B. Furthermore, (3) in ECR, the electrons absorb the energy of the electric field resonantly, so that the intensity of discharge is extremely high via ECR with the same induction electric field E, compared to the case where no magnetic field is applied. Points (2) and (3) also show in principle that the generation region of ions and radicals in the plasma differ between the case where there is no magnetic field and the case where an ECR plane is formed. Of course, in the embodiment shown in FIG. 1, the shape of the ECR plane and the vertical position of the ECR plane with respect to the vacuum chamber top member can be changed greatly by changing the currents flown through the upper and lower magnetic field coils 81 and 82 and the shape of the yoke 83, so that the generation region of ions and radicals in the plasma can be changed significantly when the ECR plane is formed compared to when no magnetic field is applied.

Furthermore, the state of diffusion differs when the ECR plane is formed compared to when no magnetic field is applied. The ions and electrons in the plasma are charged particles having a property to be easily diffused along the magnetic field but not easily diffused perpendicularly with respect to the magnetic field. This is because electrons are diffused along the magnetic field lines in the state being wound around the magnetic field lines via Larmor motion, and ions are diffused in the same direction as the electrons by the requirement of the quasi-neutral conditions of plasma. However, since radicals are neutral particles, the diffusion thereof is not influenced by the magnetic field. In other words, the formation of the ECR plane not only changes the generation region of ions and radicals but also influences the shape of distribution by the diffusion of ions and radicals. Thus, the magnetic field is an extremely useful means for controlling the plasma generation distribution and diffusion. FIGS. 18C, 18D and 18E are views corresponding to FIGS. 13C, 13D and 13E, showing the patterns of the generation region of plasma when the shape of the vacuum chamber top member 12 formed of insulating material is respectively changed to a hollow semispherical or dome shape, a trapezoidal rotated body with a space formed in the interior thereof, and a cylindrical shape with a bottom. Of course, since the sizes of the space and the surface area formed by the respective vacuum chamber top members differ, the differences in diffusion and elimination described with reference to FIG. 13 are the same in principle.

One more thing can be said with respect to FIG. 18. According to the present invention, there is no need for a vertical vacuum chamber, which is specifically required when using helicon waves as taught in patent document 5. As shown in FIG. 18B, the present invention enables to freely select between a horizontal vacuum chamber as shown in FIG. 18B and a vertical vacuum chamber as shown in FIG. 18E. In the case where helicon waves are excited, the absorption length must be set as long as possible (the vacuum chamber must be long) so that the propagated helicon waves are sufficiently absorbed during propagation, whereas according to the present invention, the energy of the electric field is absorbed by the ECR plane, so that it does not require a long absorption length. According to the present invention, the space for absorbing the energy of the induction electric field merely requires a size large enough to form the ECR plane (isomagnetics field plane and rotational plane of electrons), since the ECR plane is merely a resonant plane, instead of waves that are propagated in a certain direction. This is the significant difference between the case where helicon wave is used and the case where the ECR plane is used, and the reason why the present invention is sufficiently useful compared to the case where helicon plasma source is used.

As mentioned, the present invention has three contrivances for controlling the generation, the diffusion and the elimination of plasma, which are (1) the antenna structure, (2) the structure of the top member 12 of the vacuum chamber formed of insulating material, and (3) magnetic field. These features could not be easily realized by the prior art ICP source, the ECR plasma source or the parallel plate-type plasma source. Especially, the present invention can control the plasma generating region and the diffusion thereof more dynamically using the magnetic field by changing the currents flown through the upper and lower magnetic field coils 81 and 82, even after determining the apparatus structure such as the antenna structure and the shape of the vacuum chamber top member 12.

### Embodiment 2

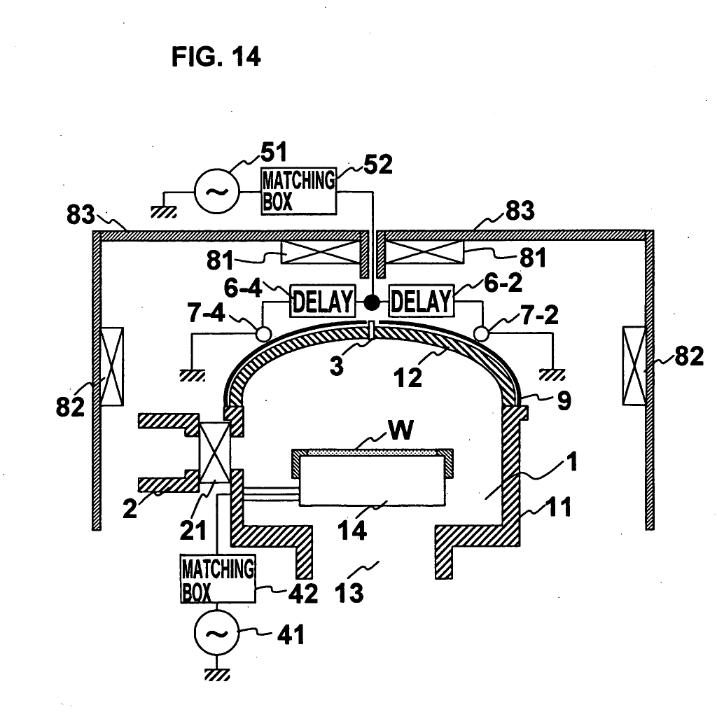

A second example of the shape of the vacuum chamber top member will be described with reference to FIG. 14 as a second embodiment. In FIG. 14, the structure of the plasma processing apparatus other than the shape of the vacuum processing chamber top member 12 is the same as that of the plasma processing apparatus of FIG. 1, and the same components are denoted by the same reference numbers, so that the descriptions thereof are omitted. The vacuum processing chamber top member 12 of FIG. 1 is composed of a planar (disk-shaped) insulating member, but according to the present example, the vacuum processing chamber top member 12 formed of insulating material is formed in the shape of a hollow hemispherical shape or dome shape, which is airtightly fixed to the top of the cylindrical vacuum chamber 11 as illustrated to constitute the vacuum processing chamber 1. According to this arrangement, as shown in FIG. 18C, a plasma generating region is formed on the ECR plane.

### Embodiment 3

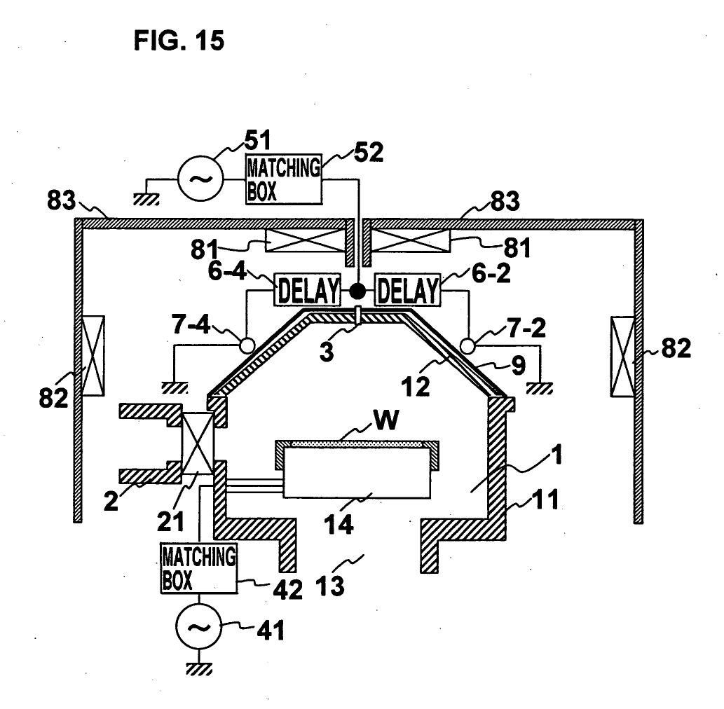

A third example of the shape of the vacuum chamber top member will be described with reference to FIG. 15 as a third embodiment. In FIG. 15, the structure of the plasma processing apparatus other than the shape of the vacuum processing chamber top member 12 is the same as that of the plasma processing apparatus of FIG. 1, and the same components are denoted by the same reference numbers, so that the descriptions thereof are omitted. In the present example, the vacuum processing chamber top member 12 formed of insulating material has a shape in which the top portion of a hollow circular cone is cut off to form a flat ceiling and a space is formed in the interior thereof, which is airtightly fixed to the top of the cylindrical vacuum chamber 11 as illustrated to form the vacuum processing chamber 1. In the specification, this shape of the vacuum chamber top member 12 is called a trapezoidal rotated body. According to this arrangement, a plasma generation region P is formed on the ECR plane, as shown in FIG. 18D.

### Embodiment 4

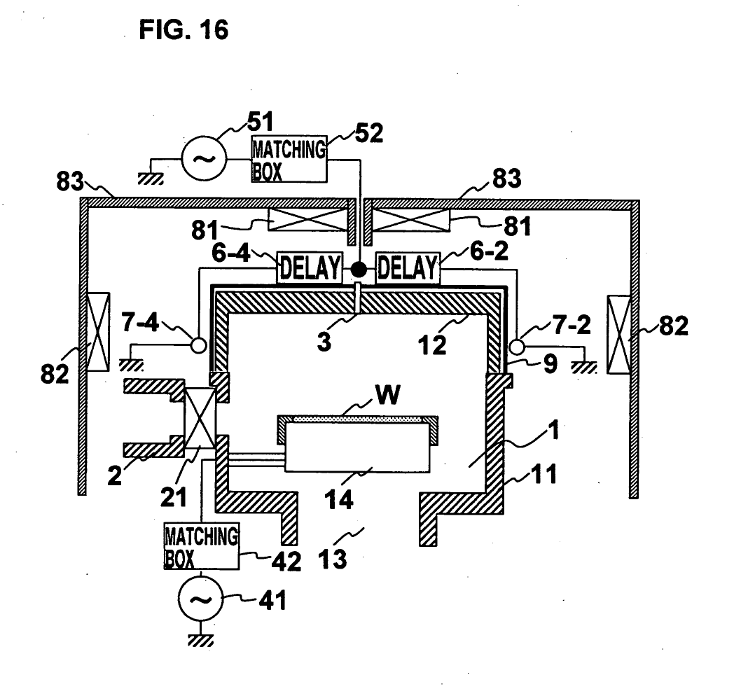

A forth example of the shape of the vacuum processing chamber top member will be described with reference to FIG. 16 as a fourth embodiment. In FIG. 16, the structure of the plasma processing apparatus other than the shape of the vacuum processing chamber top member 12 is the same as that of the plasma processing apparatus of FIG. 1, and the same components are denoted by the same reference numbers, so that the descriptions thereof are omitted. In the present example, the vacuum processing chamber top member 12 is formed into a cylindrical shape with a bottom, which is airtightly fixed to the top of the cylindrical vacuum chamber 11 with the bottom disposed upward. In the specification, this shape of the vacuum chamber top member 12 is called a cylindrical shape with a bottom. According to this arrangement, a plasma generation region P is formed on the ECR plane as shown in FIG. 18E.

According to these embodiments, the functions thereof are the same as those shown in FIG. 1. The difference is that the ranges of distribution control of ions and radicals of plasma (the generation region and the level of diffusion and elimination thereof) generated by the respective plasma sources differ. The selection of the plasma source should depend on the type of the process to which the present invention is applied.

### Embodiment 5

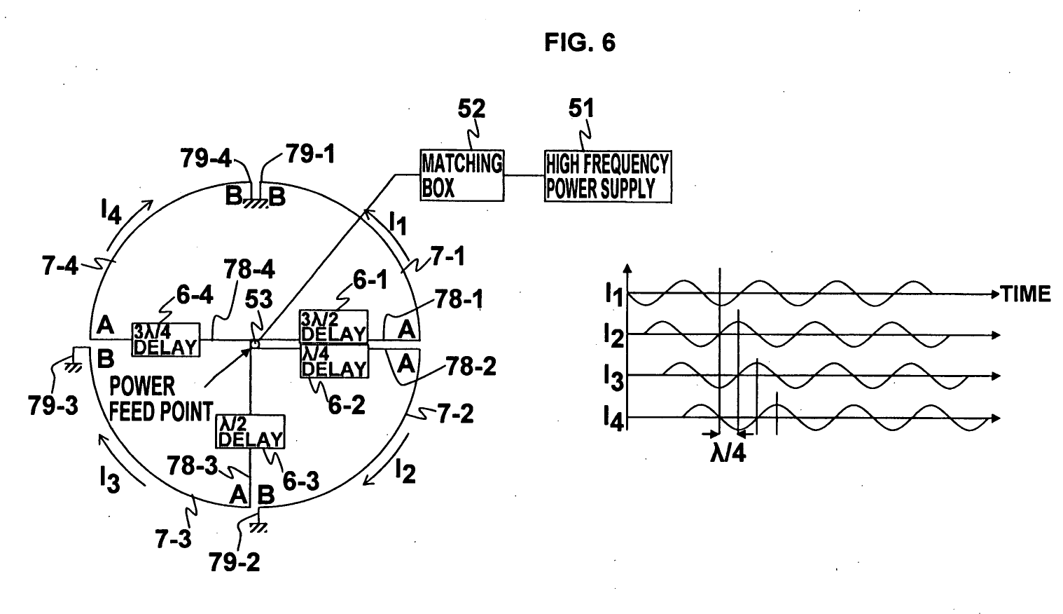

In FIG. 1 (FIG. 2), the power feed ends A and the grounded ends B of the circular arc-shaped high frequency induction antenna elements 7-1, 7-2, 7-3 and 7-4 in which a circle is divided into four parts are arranged point-symmetrically in the order of ABABABAB on a single circumference. However, this arrangement that “the power feed ends and the grounded ends are arranged point-symmetrically” is not an essential arrangement for realizing the first point of the aforementioned necessary and sufficient conditions. The power feed ends A and the grounded ends B can be arranged freely. An embodiment corresponding to FIG. 2 is illustrated in FIG. 6 as a fifth embodiment. FIG. 6 shows an example where the positions of the power feed ends A and the grounded ends B of the high frequency induction antenna elements 7-1 are reversed and the direction of the high frequency current I1 is reversed. In this example, however, the rotating induction electric field E can be created by reversing the phase of the high frequency current I1 flown through the high frequency induction antenna element 7-1 with respect to the phase shown in FIG. 2 (for example, by delaying the same by 3λ/2). What can be understood from this embodiment is that the reversing of positions of the power feed ends A and the grounded ends B is equivalent to reversing the phase, that is, to delaying the phase by λ/2.

### Embodiment 6

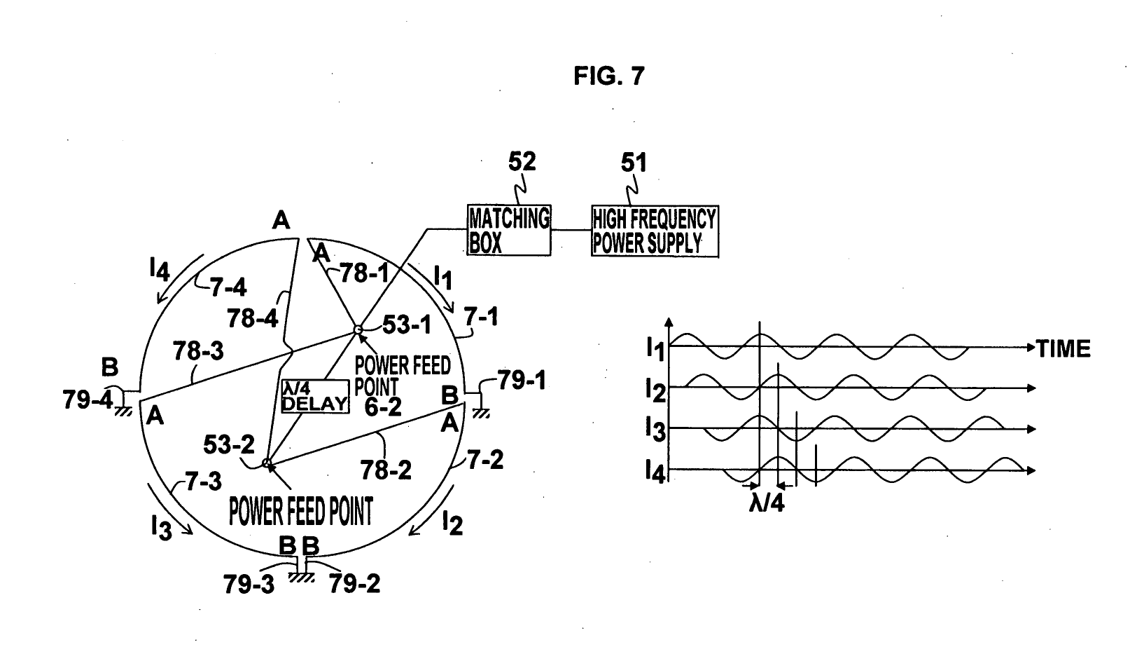

The arrangement of FIG. 2 can be further simplified using the above feature, which is illustrated in FIG. 7 as a sixth embodiment. The arrangement of FIG. 7 utilizes the fact that and I₃, and I₂ and I₄, are respectively delayed by λ/2, that is, reversed, wherein the currents of the same phase are respectively flown to I₁ and I₃, and to I₂ and I₄, but the power feed ends A and the grounded ends B of I₃ and I₄ are reversed. Further, a λ/4 delay 6-2 is inserted between I₁ and I₃, and I₂ and I₄, so that a rotating induction electric field E similar to FIG. 2 (shown in FIG. 5) can be formed. As described, many variations can be formed by combining the arrangement of the high frequency induction antenna and phase control. However, these variations are merely a design matter, and all arrangements satisfying the first content of the aforementioned necessary and sufficient conditions constitute an embodiment of the present invention.

### Embodiment 7

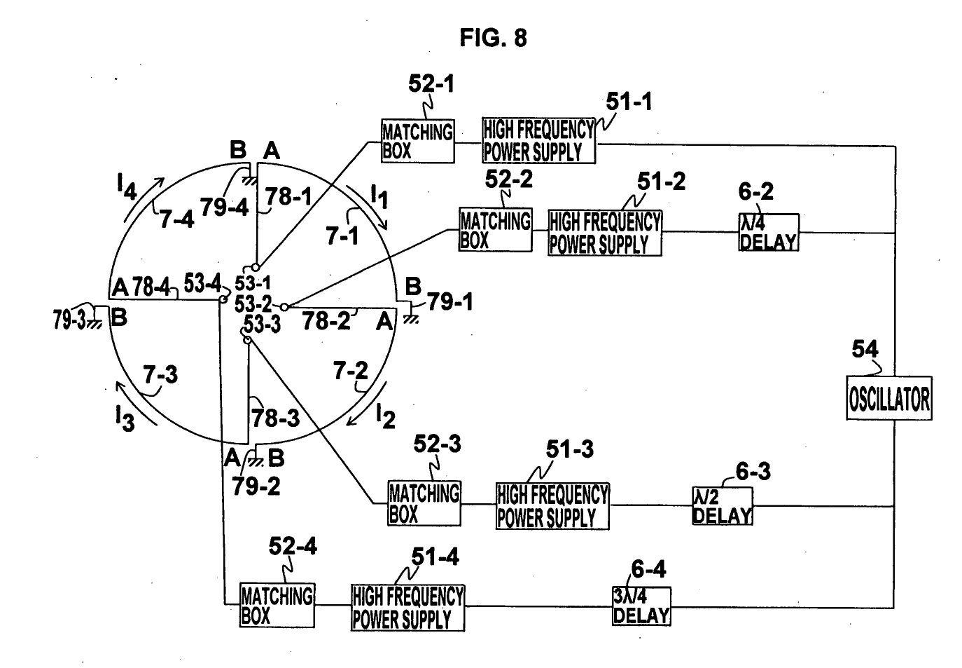

In FIG. 1, a phase delay circuit is disposed between the matching box disposed in the power supply output unit and the high frequency induction antenna elements 7-1 through 7-4. This arrangement that “a phase delay circuit is disposed between the matching box and the high frequency induction antenna elements 7-1 through 7-4” is not a necessary structure for realizing the first content of the aforementioned necessary and sufficient conditions. In order to satisfy the content of the first necessary and sufficient conditions, it is merely necessary to supply a current to the high frequency induction antenna so as to form a rotating induction electric field E as illustrated in FIG. 5. In the present embodiment, a rotating induction electric field E shown in FIG. 5 is formed similarly as FIG. 2, but an embodiment having a different structure is illustrated in FIG. 8 as a seventh embodiment. The arrangement of FIG. 8 supplies current to flow through the high frequency induction antenna elements 7-1 through 7-4 from the same number of high frequency power supplies 51-1 through 51-4 as the high frequency induction antenna elements 7-1 through 7-4, wherein the high frequency power supplies 51-1 through 51-4 and matching boxes 52-1 through 52-4 are connected to the output of a single oscillator 54 respectively via no delay means, via a λ/4 delay means 6-2, via a λ/2 delay means 6-3, and a 3λ/4 delay means 6-4, so as to perform the necessary phase delays. In this way, by increasing the high frequency power supply 51, the number of matching circuits 53 are increased, but the power quantity of a single high frequency power supply can be reduced, and the reliability of the high frequency power supply can be improved. Furthermore, the plasma uniformity in the circumferential direction can be controlled by fine-adjusting the power supplied to the respective antennas.

### Embodiment 8

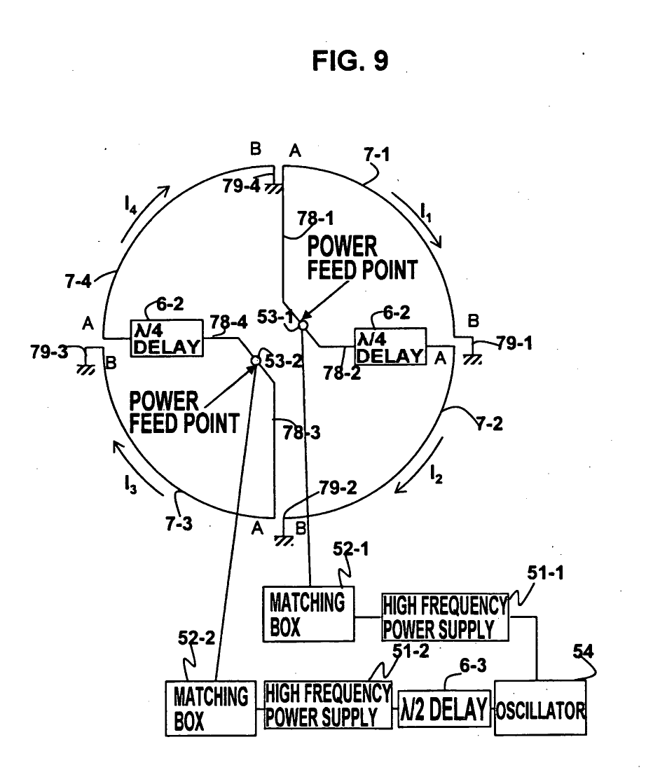

The variation of the power supply structure and the high frequency induction antenna structure is not restricted to the one described above. For example, a rotating induction electric field E as shown in FIG. 5 can be formed similar to FIG. 2 by applying the arrangements shown in FIGS. 2 and 8, but an even further variation of arrangement is possible. One embodiment of which is illustrated in FIG. 9 as an eighth embodiment. According to the embodiment of FIG. 9, high frequencies mutually delayed by λ/2 are output to the power feed points 53-1 and 53-2 from two high frequency power supplies, which are the high frequency power supply 51-1 connected to the oscillator 54 and the high frequency power supply 51-2 connected via the λ/2 delay means 6-3, and λ/4 delay means 6-2 are further disposed between the outputs thereof and the high frequency induction antenna elements 7-2 and 7-4 to perform the necessary delays.

### Embodiment 9

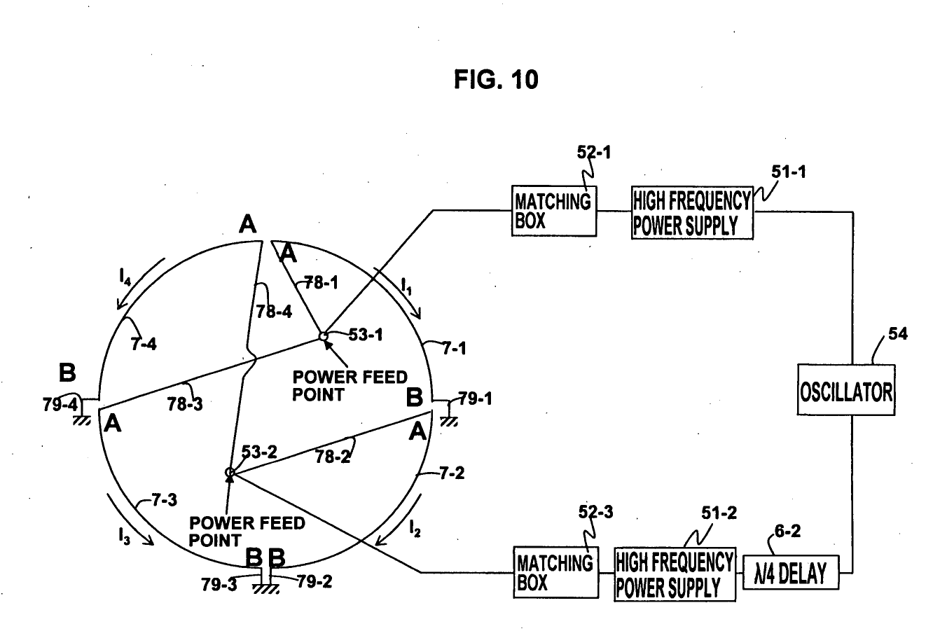

The next embodiment combines the embodiments of FIG. 9 and FIG. 7, which is illustrated in FIG. 10 as a ninth embodiment. In FIG. 10, two high frequency power supplies 51-1 and 51-2 connected to the oscillator 54 are used similar to FIG. 9, but a λ/4 delay means 6-2 is inserted to one side having the high frequency power supply 51-3 of the output of the oscillator 54 to delay the phase by λ/4, wherein the high frequency induction antenna elements 7-1 and 7-2 are set so that the power feed ends A and the grounded ends B are arranged similarly as FIG. 9, and the high frequency induction antenna elements 7-3 and 7-4 are set so that the power feed ends A and the grounded ends B are opposite to (reversed from) those of the high frequency induction antenna elements 7-1 and 7-2, similar to FIG. 7. When the reference of the phase of the output is set as the phase of I1, the currents of I₁ and I₃ are of the same phase, but since the direction of I₃ (the power feed end A and the grounded end B) is reversed from FIG. 2, the induction electric field E formed by I₁ and I₃ will be the same as FIG. 2. Further, since the currents of I₂ and I₄ of the same phase have its phase delayed by λ/4 from I₁, but since the direction of I₄ (the power feed end A and the grounded end B) is reversed from FIG. 2, the same induction electric field E as that of FIG. 2 is formed by I₂ and I4. The embodiment shown in FIG. 10 forms the same induction electric field E as that of FIG. 2 via an arrangement different from that of FIG. 2.

In other words, the present embodiment relates to a plasma processing apparatus comprising a vacuum chamber constituting the vacuum processing chamber for storing a sample, a gas inlet for feeding processing gas into the vacuum processing chamber, a high frequency induction antenna disposed outside the vacuum processing chamber, a magnetic field coil forming a magnetic field within the vacuum processing chamber, a plasma generating high frequency power supply for supplying the high frequency current to the high frequency induction antenna, and a power supply for supplying power to the magnetic field coil, wherein a high frequency current is supplied from the high frequency power supply to the high frequency induction antenna so as to turn the gas fed to the vacuum processing chamber into plasma and to process the sample using plasma, wherein the high frequency induction antenna is divided into s-number (s is a positive even number) of high frequency induction antenna elements, and the respective divided high frequency induction antenna elements are aligned tandemly on a circumference, wherein high frequency currents respectively delayed in advance by λ (wavelength of high frequency power supply)/s from the respective s/2 number of high frequency power supplies are sequentially supplied from the first high frequency induction antenna element to the s/2^{nd} high frequency induction antenna element, and high frequency currents having the same phase as the first to s/2^{nd} high frequency induction antenna elements respectively opposed thereto are sequentially supplied from the s/2+1^{st} high frequency induction antenna element to the s-th high frequency induction antenna element. In this example, the high frequency induction antenna elements are formed so that the direction of currents flowing through the high frequency induction antenna elements are reversed, so as to form an electric field rotated in a fixed direction in order to subject the sample to plasma processing, according to which currents are flown in a sequentially delayed manner in the right direction with respect to the direction of the magnetic field lines of the magnetic field formed by supplying power to the magnetic field coil, thereby forming an electric field rotating in a specific direction and generating plasma so as to subject the sample to plasma processing.

In FIG. 1 (FIG. 2), circular arc-shaped high frequency induction antenna elements 7-1, 7-2, 7-3 and 7-4 in which a circle is divided into four parts are arranged on a single circumference. This arrangement in which the antenna is “divided into four parts” is not a necessary arrangement for realizing the first point of the aforementioned necessary and sufficient conditions. The number in which the high frequency induction antenna is divided can be any integral number n satisfying n≧2. It is possible to form the high frequency induction antenna 7 on a single circumference using n-numbers of circular arc-shaped antennas (high frequency induction antenna elements). FIG. 1 illustrates a method for forming an induction electric field E that rotates in the right direction with respect to the direction of the magnetic field lines by controlling the phase of currents flown to the high frequency, which can surely be realized when n≧3. The case where n=2 is irregular, and for example, two semicircular antennas are used to constitute a single circumference, and currents are flown therethrough with a phase difference of)(360°/(two antennas)=)(180°). In this case, the induction electric field E can rotate both in the right direction and the left direction when a current is simply flown therethrough, so that it seems as if the contents of the first point of the aforementioned necessary and sufficient conditions is not satisfied. However, when a magnetic field satisfying the necessary and sufficient conditions according to the present invention is applied, the electrons are self-activated to rotate in the right direction, and as a result, the induction electric field E is also rotated in the right direction. Therefore, the number in which the high frequency induction antenna is divided in the present invention can be any integral number n satisfying n≧2.

### Embodiment 10

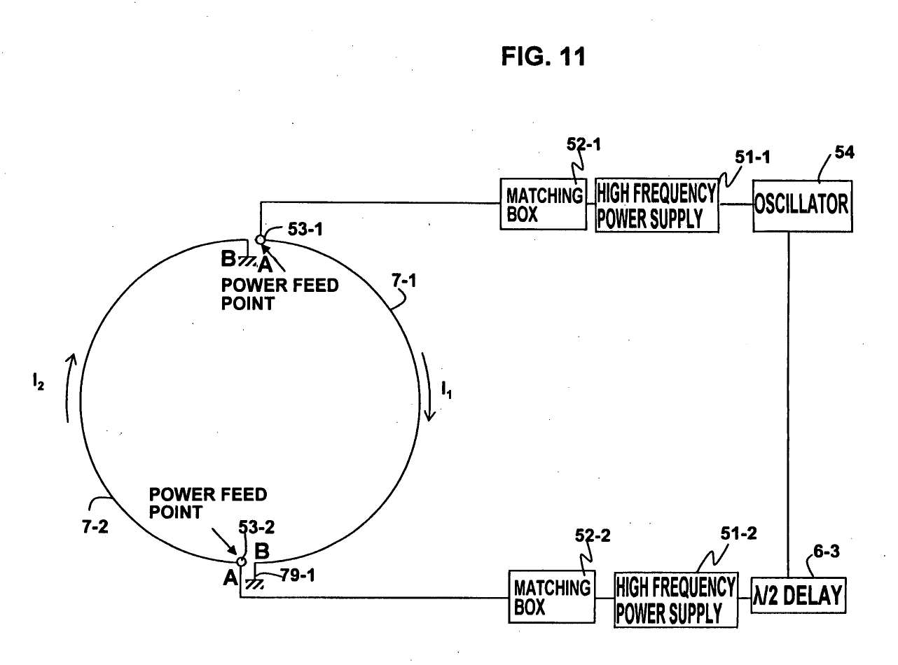

As described, when the division number n of the high frequency induction antenna is n=2, by applying thereto a magnetic field B satisfying the second content of the aforementioned necessary and sufficient conditions, the induction electric field E formed by the high frequency induction antenna rotates in the right direction with respect to the direction of the magnetic field lines. In the present embodiment, high frequencies with a λ/2 phase shift are supplied to the two high frequency induction antenna elements. FIG. 11 shows the basic arrangement of the present embodiment, which is the tenth embodiment. In the arrangement of FIG. 11, the power feed end A and the grounded end B of the antenna element 7-1 and the power feed end A and the grounded end B of the antenna element 7-2 are arranged point symmetrically so that they are aligned in the order of ABAB in the circumferential direction, and one of the two outputs of the oscillator 54 is connected via a high frequency power supply 51-1 and a matching box 52-1 to the feeding point 53-1 of the power feed end A of the high frequency induction antenna element 7-1, and the other one is connected via a λ/2 delay means 6-3, a high frequency power supply 51-2 and a matching box 52-2 to the power feed point 53-2 of the power feed end A of the high frequency induction antenna element 7-2.

Accordingly, as illustrated in FIG. 11, the directions of the currents of the respective high frequency induction antenna elements are as shown by the arrows I1 and I2. However, currents having their phases reversed (with a λ/2 phase shift) are supplied to elements 7-1 and 7-2 of the high frequency induction antenna, so as a result, the direction of the high frequency currents flown to the respective high frequency induction antenna elements 7-1 and 7-2 is changed between upward and downward directions in the drawing every half cycle of the phase. Therefore, the induction electric field E formed by FIG. 11 has two peaks, similar to FIG. 5. However, according to this arrangement, the electrons driven by the induction electric field E can rotate both in the right direction and the left direction. However, when a magnetic field B satisfying the aforementioned necessary and sufficient conditions (magnetic field having magnetic field lines directed from the front side of the paper plane toward the back side thereof) is applied, the electrons rotated in the right direction receive high frequency energy resonantly via the ECR phenomenon, and cause highly efficient avalanche ionization, but the electrons rotated in the left direction do not receive high frequency energy resonantly, and the ionization efficiency thereof is not good. As a result, the plasma is generated mainly by the electrons rotated in the right direction, and only the electrons accelerated to high speed by receiving the high frequency energy efficiently will remain. At this time, the current components flown through the plasma are mainly composed of low-speed electrons rotated in the left direction and high-speed electrons rotated in the right direction, and obviously, the high-speed electrons rotated in the right direction become dominant, so as shown in expressions (1) and (2), the induction electric field E is rotated in the right direction. This is the same phenomenon as the prior art ECR plasma source using μ wave, UHF or VHF, in which ECR discharge is caused even if the electric field is not especially rotated in a specific direction.

### Embodiment 11

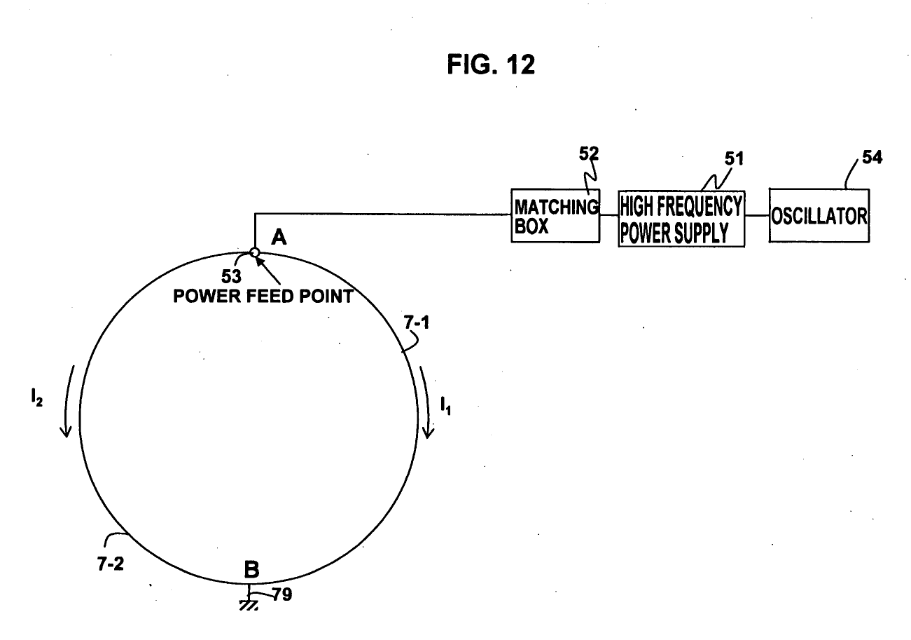

When the effect of FIG. 6 (or FIG. 7 or FIG. 10) is applied to FIG. 11, the ECR phenomenon can be caused with a more simple arrangement as shown in FIG. 12 illustrating the eleventh embodiment of the present invention. In FIG. 12, there is no supply of high frequencies having reversed phases, and high frequencies of the same phase are supplied to the respective high frequency induction antenna elements, but since the power feed ends A and the grounded ends B of the respective high frequency induction antenna elements are the same, the direction of the currents are reversed, and the effects equivalent to FIG. 11 can be achieved. However, if the division number n of the high frequency induction antenna is n=2, there are cases where the currents flown to two high frequency induction antenna elements turn zero simultaneously, so that a moment occurs exceptionally when the induction electric field E equals 0. When the division number n of the high frequency induction antenna is n≧3, current is constantly flown to two or more high frequency induction antenna elements, so that no moment occurs when the induction electric field E equals 0, which can be made clear by forming a drawing similar to FIG. 3 for the respective cases.

An arrangement is taught (refer for example to patent document 6) where at least three linear conductors are arranged radially at equal intervals from the center of the antenna, and wherein one end of the respective linear conductors is grounded and the other end is connected to an RF high frequency power supply. In FIGS. 3C and 3E of patent document 6, (a) the antenna is introduced in vacuum, (b) the antenna is composed of linear conductors, (c) the linear conductors are covered with insulation material, and (d) a magnetic field is applied thereto. This arrangement is similar to the arrangement where n equals 2 illustrated in FIG. 12 of the present invention. The object of the arrangement of patent document 6 is to supply a large amount of power stably to the antenna placed in vacuum to generate high density plasma, and the diffusion thereof is controlled via a magnetic field so as to achieve a uniform distribution. This arrangement, however, has a fatal defect compared to the present invention. The basic cause thereof is that the antenna is placed in vacuum. As disclosed in the document, when the conductor of the antenna is placed in vacuum, it becomes difficult to generate plasma stably due to abnormal discharge and the like. This is a fact also disclosed in non-patent document 3: M. Yamashita et al., Jpn. J. Appl. Phys., 38, 1999, pp 4291. Therefore, according to the invention of patent document 6, the conductors are formed as linear conductors covered by insulating material so as to stabilize the antenna and be insulated from plasma. However, the antenna is not only inductively coupled with plasma, but also capacitively coupled with plasma. In other words, the antenna conductor and the plasma are connected via capacitance of the insulation coating, and a self bias voltage via high frequency voltage occurs on the surface of the insulation coating exposed to plasma, so that the surface of the insulation coating is constantly sputtered by ions in the plasma. A problem occurs thereby. At first, since the insulation coating is sputtered, the semiconductor wafer subjected to plasma processing is contaminated by the material substance of the insulation coating, or the particles generated by the sputtering of the insulation coating is attached to the surface of the semiconductor wafer, inhibiting normal plasma processing. Another problem occurs when the insulation coating is thinned with time, and the capacitance of the insulation coating is increased, by which the capacitive coupling between the conductor of the antenna and the plasma becomes stronger. Thereby, the property of plasma generated via capacitive coupling is varied with time, so that it becomes impossible to generate plasma with stable characteristics. In other words, the plasma characteristics are varied with time. Further, when the insulation coating is thinned and capacitive coupling is increased, higher self bias voltage occurs, by which the insulation coating is consumed at an accelerated pace, causing particles and contamination at an accelerated pace. Finally, the weakest insulation coating portion is broken, and the conductor of the antenna is exposed to plasma directly and abnormal discharge occurs, according to which plasma processing can no longer be continued. Of course, the lifetime of the antenna is limited. In other words, the arrangement of the invention disclosed in patent document 6 cannot be applied to industrial production. The arrangement can be used at first, but the characteristics thereof are deteriorated with time and the antenna must be replaced as a consumed component, so that the apparatus requires much maintenance time and cost. In contrast, according to the arrangement of the present invention, the antenna is arranged on the atmospheric side of the top member 12 formed of insulating material, and the lifetime thereof is semipermanent, so that the apparatus requires no maintenance time and costs related to replacing the antenna as consumed component. Further, as shown in FIG. 1, a Faraday shield exists between the antenna and the plasma, so that the capacitive coupling of the antenna and plasma can be shielded. Therefore, the top member 12 formed of insulating material is prevented from being sputtered by ions and causing particles and other contaminants from falling on the semiconductor wafer, and the top member 12 will not be thinned through sputtering and consumed. Another difference between the present invention and the invention disclosed in patent document 6 is that the invention of patent document 6 neither intends to create a rotating induction electric field nor cause ECR via the rotating induction electric field and the magnetic field.

In FIG. 1 (FIG. 2), the high frequency induction antenna elements 7-1, 7-2, 7-3 and 7-4 having a circular shape divided into four parts is arranged on a single circumference. This arrangement where the antenna elements are arranged on “a single circumference” is not a necessary arrangement for realizing the first content of the aforementioned necessary and sufficient conditions. For example, if the high frequency induction antenna is divided into four parts and arranged at the inner and outer circumferences of the planar insulating body 12, divided into upper and lower portions or divided obliquely, the first content of the aforementioned necessary and sufficient conditions can still be realized. In other words, if the first content of the aforementioned necessary and sufficient conditions can be realized, the number of circumferences or the arrangements thereof can be determined arbitrarily. Similar to the case of the planar vacuum chamber top member 12, even if the shape of the vacuum chamber top member 12 composed of insulating material is a trapezoidal rotated shape, a hollow semispherical shape or dome shape, or a cylindrical shape with a bottom, the high frequency induction antennas can be arranged on the inner circumference and the outer circumference thereof, or on upper and lower areas thereof, or obliquely.

The following embodiment of the present invention relates to providing multiple sets of high frequency induction antennas composed of multiple high frequency induction antenna elements. In the example, the number of sets of antennas composed of multiple high frequency induction antenna elements for forming a rotating induction electric field E is referred to as m. In the present invention, m can be any natural number. In other words, the divided antenna elements can be arranged on three or more circumferences. The examples shown in FIGS. 1, 2, 6 through 12 and 14 through 16 all show cases where m equals 1. The number of m should be determined according to the aim of the process. In industrial application, the number of m should be determined by considering the level of the required area of the plasma, the level of the area of the object to be processed, and the required level of uniformity of the plasma. There is a definite difference between the case where m equals 1 and where m equals two or more. As described in detail later, compared to the case where m equals 1, when m equals two, there will be one more tuning knob for controlling the generation and distribution of plasma by controlling the level of the currents supplied to the respective sets of antennas. The example where m equals three or more is too complex, so we will describe an example where m equals 2.

### Embodiment 12

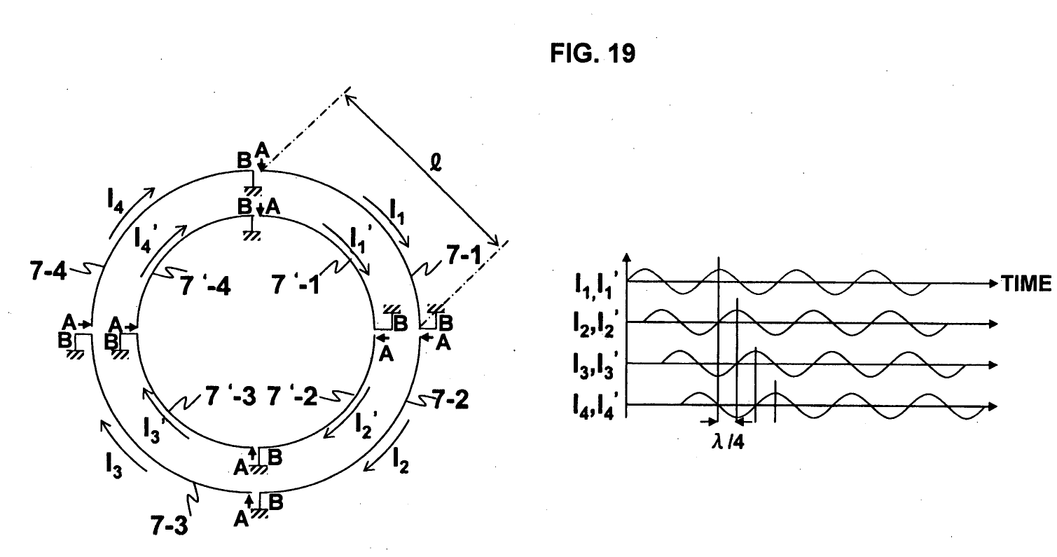

The twelfth embodiment of the present invention will be described with reference to FIG. 19. FIG. 19 shows a case where the arrangement of FIG. 2 or FIG. 8 (m=1) is expanded to m=2 (multiple sets). The high frequency power supply, the matching box, the delay circuits for current and the power feed lines are omitted from the drawing for sake of easier understanding, and only the power feed ends A (arrows) and the grounded ends B of the respective high frequency induction antenna elements are illustrated. FIG. 19 includes antenna elements 7′-1, 7′-2, 7′-3 and 7′-4 as pairs respectively disposed on the inner sides of the high frequency induction antenna elements 7-1, 7-2, 7-3 and 7-4 illustrated in FIG. 2 or FIG. 8. Hereafter the high frequency induction antenna elements 7-1, 7-2, 7-3 and 7-4 are referred to as the outer antenna 7, and the high frequency induction antenna elements 7′-1, 7′-2, 7′-3 and 7′-4 are referred to as the inner antenna 7′. In order to generate a plasma with high uniformity, the outer antenna 7 and the inner antenna 7′ should be arranged as concentric circles. Further according to this arrangement, for example, the phase angles of the power feed ends A and the grounded ends B in the circumferential direction of the high frequency induction antenna element 7-1 and the counterpart antenna element 7′-1 correspond. In the example, as shown in the right side of FIG. 19, currents having a same phase are supplied as I₁ and I₁', and currents with phases respectively delayed by λ/4 are supplied as I₂ and I₂′, I₃ and I₃′, and I₄ and I₄′. In this example, the sum of the induction electric field (induction magnetic field) created by currents I₁ and I₁′ becomes highest, and the transfer efficiency of power from the antenna to plasma becomes maximum. The generation of plasma is mainly performed by the inner antenna 7′ for the inner portion of the inner antenna 7′ (which is in a circle), and mainly performed by the outer antenna 7 for the outer circumference of the outer antenna 7 (which is in a circular ring). Therefore, the distribution control of plasma can be realized by changing the ratio of the absolute value of currents |I₁| (=|I₂|=|I₃|=|I₄|) and |I₁′| (=|I₂′|=|I₃′|=|I₄′|). This is a new tuning knob that could not be achieved when m equals 1. The current ratio |I₁′|/|I₁| can be set arbitrarily from zero (|I₁′|=0, |I₁| being a finite value) to infinity (|I₁′| being a finite value, |I₁|=0).

In the present invention, a single set of high frequency induction antennas must have its current phase controlled within the set of high frequency induction antennas, as described with reference to FIG. 2. This is also true for the outer antenna 7 (the high frequency induction antenna elements 7-1, 7-2, 7-3 and 7-4) and the inner antenna 7′ (the high frequency induction antenna elements 7′-1, 7′-2, 7′-3 and 7′-4) of FIG. 19. Further, in the example illustrated in FIG. 19, the phase difference of the currents of the outer antenna 7 and the inner antenna 7′ is controlled to 0°. However, in the arrangement of FIG. 19, the phase difference between the inner and outer antennas is not necessarily controlled to 0°. The electric field (magnetic field) is a physical quantity capable of being added and subtracted, and the induction electric field created by the outer antenna and the induction electric field created by the inner antenna are necessarily mutually strengthened at some areas and mutually weakened at other areas. When the phase difference in FIG. 19 is 0°, it means that the mutually weakening electric field is minimized and the mutually strengthening electric field is maximized. Therefore, the transfer efficiency of power from the antenna to the plasma becomes maximum. When the difference is not 0°, the mutually weakening electric field is increased and the mutually strengthening electric field is decreased compared to when the difference is 0°. From the viewpoint of distribution control of plasma, it is not necessary to minimize the mutually weakening electric field and to maximize the mutually strengthening electric field. The phase difference of currents in the inner antenna and the outer antenna are set to 0° in FIG. 19 for better understanding, but it can also be set to values other than 0°.

### Embodiment 13

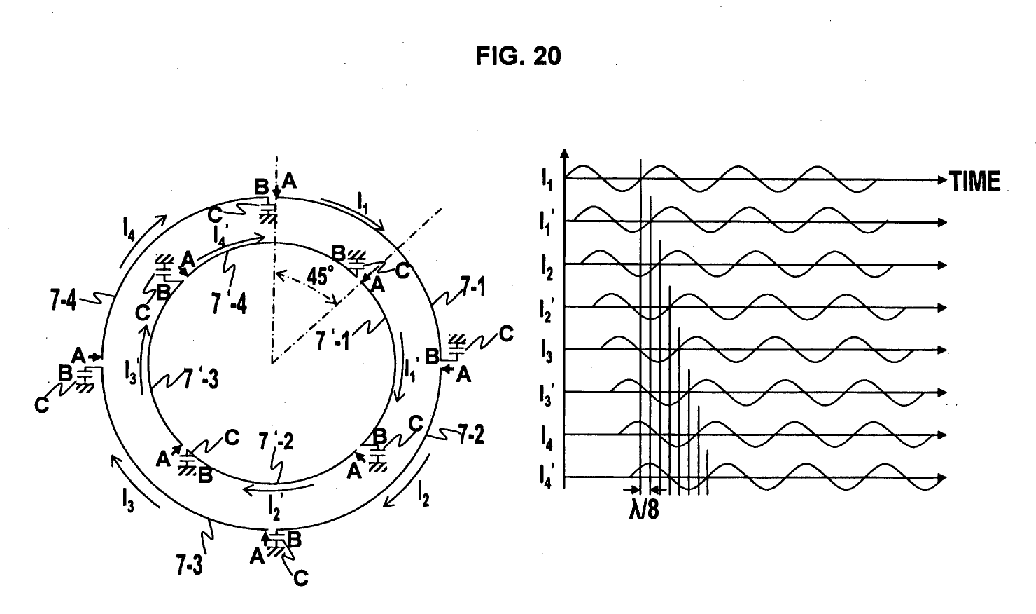

The thirteenth embodiment of the present invention will be described with reference to FIG. 20. FIG. 20 shows an embodiment in which the phase difference of currents of the outer antenna and the inner antenna are set to 45°. In this example, the number of high frequency induction antenna elements (the number into which the antenna is divided) is n=4, so 45° corresponds to 2π/mn (radian). In FIG. 20, the outer antenna is displaced by 45° from the inner antenna in the circumferential direction so that the electric field created by the inner antenna 7′ and the outer antenna 7 become strongest. This means that the power feed end A of the high frequency induction antenna element 7-1 of the outer antenna and the power feed end A of the high frequency induction antenna element 7′-1 of the inner antenna are rotated for 45° in the circumferential direction. According to this arrangement, the phase difference of currents supplied to the respective high frequency induction antenna elements is, as shown in the right side of FIG. 20, 45° (λ/mn).

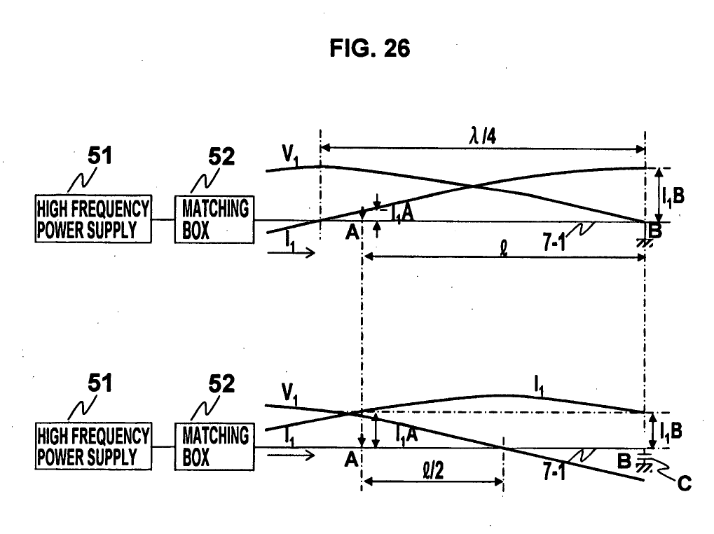

The arrangement of FIG. 20 is advantageous compared to the arrangement of FIG. 19. The disadvantages of the arrangement of FIG. 19 will now be described. Similar to FIG. 2, the condition in which the induction electric field created by the outer antenna 7 of FIG. 19 rotates smoothly is when the length 1 of a single high frequency induction antenna element, such as element 7-1, satisfies 1≦λ/n (when the outer antenna satisfies 1≦λ/n, the inner antenna necessarily satisfies 1≦λ/n, so only the outer antenna is considered in this description). When 1<<λ/n, the high frequency current I1A flown through the power feed end A of the antenna element 7-1 and the high frequency current I1B flown through the grounded end B are considered to be equal, so that I1A equals I1B. However, when 1 approximates the length of λ/n, a current distribution occurs in the high frequency induction antenna elements by the standing wave (wavelength λ). This state is shown in the upper side of FIG. 26. The impedance in the direction I₁ (the direction of the arrow) observed from the power feed end A will be a certain limited impedance (described later as L) of the antenna element 7-1, whereas the impedance in the direction I1 observed from the grounded end B will substantially be 0Ω. Therefore, when the influence of the standing wave is significant, normally a state of I₁A<I₁B is realized as shown in the upper side of FIG. 26. Naturally, the induction electric field intensity E immediately below the power feed end A, that is, the density of plasma, becomes smaller than the plasma density immediately below the grounded end B. In other words, a plasma distribution is generated in the circumferential direction of the outer antenna. The plasma distribution is most greatly varied at the joint between one antenna element and another antenna element, such as between the grounded end B of the antenna element 7-1 and the power feed end A of the antenna element 7-2.

There are two methods for making the plasma distribution in the circumferential direction more uniform. One method is to ground the grounded end B not directly but indirectly via a capacitor C, as shown in FIG. 20. By setting the value of capacitor C appropriately, it becomes possible to realize I₁A=I₁B. This state is shown in the lower area of FIG. 26. In order to realize I₁A=I₁B when the inductance of the antenna element 7-1 is referred to as L, a relationship of 1/ωC=ωL/2 must be realized between the capacitor C (capacity C) and L. As shown in the lower side of FIG. 26, at this time, the distribution of current I₁ takes a maximum value at the center of the antenna element 7-1, and the distribution of voltage V₁ satisfies 0 V at the center of the antenna element 7-1. This state is described in further detail in non-patent document 3 and non-patent document 4: K. Suzuki et al., Plasma Source Sci. Technol., 9, 2000, pp 199.

Another method is to displace the power feed end A and the grounded end B of the inner antenna in the circumferential direction with respect to the circumferential position of the power feed end A and the grounded end B of the outer antenna, that is, to provide a phase angle. The phase angle in FIG. 20 is 45°. According to this arrangement, the varied concentration of the plasma can be diffused within the chamber, and the uniformity of plasma diffusion can be improved. The arrangement of FIG. 20 satisfies these two conditions simultaneously.

### Embodiment 14

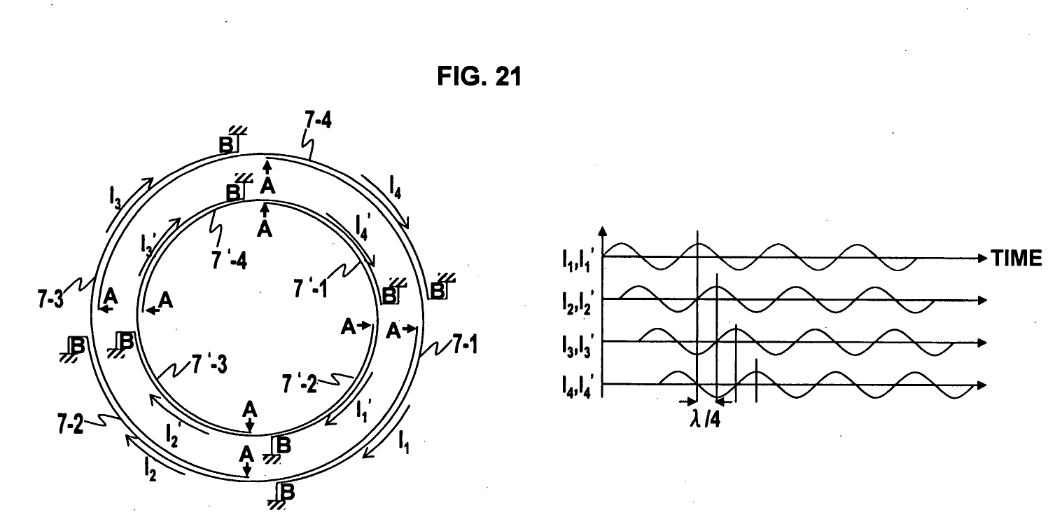

The fourteenth embodiment of the present invention will be described with reference to FIG. 21. When a plasma distribution is formed in the circumferential direction of the antenna due to the influence of the standing wave, as described in FIG. 20, there is another antenna arrangement for making the plasma distribution more uniform. The antenna elements are superposed in this arrangement, one embodiment of which is shown in FIG. 21. In FIG. 21, half of the high frequency induction antenna element 7-1 is superposed with the high frequency induction antenna element 7-4, and the remaining half thereof is superposed with the high frequency induction antenna element 7-2. Where the high frequency induction antenna elements are superposed, the induction electric fields created by the currents flown through the two high frequency induction antenna elements are added together. In other words, half of the high frequency induction antenna element 7-1 creates an induction electric field formed of currents I₁ and I₄, and the other half creates an induction electric field formed of currents I₁ and I₂. According to this arrangement, a rotating electric field can be formed with an induction electric field that is smoothed further in the circumferential direction. FIG. 21 adopts this arrangement to all the antenna elements.

With reference to FIGS. 20 and 21, a method for forming a smoother rotating electric field using an outer antenna 7 and an inner antenna 7′ have been described. The methods (1) for arranging the outer antenna and the inner antenna with a phase angle in the circumferential direction, (2) for grounding the grounded end B via a capacitor, and (3) for superposing the antenna elements were illustrated in different drawings, but the three methods can be performed simultaneously.

### Embodiment 15

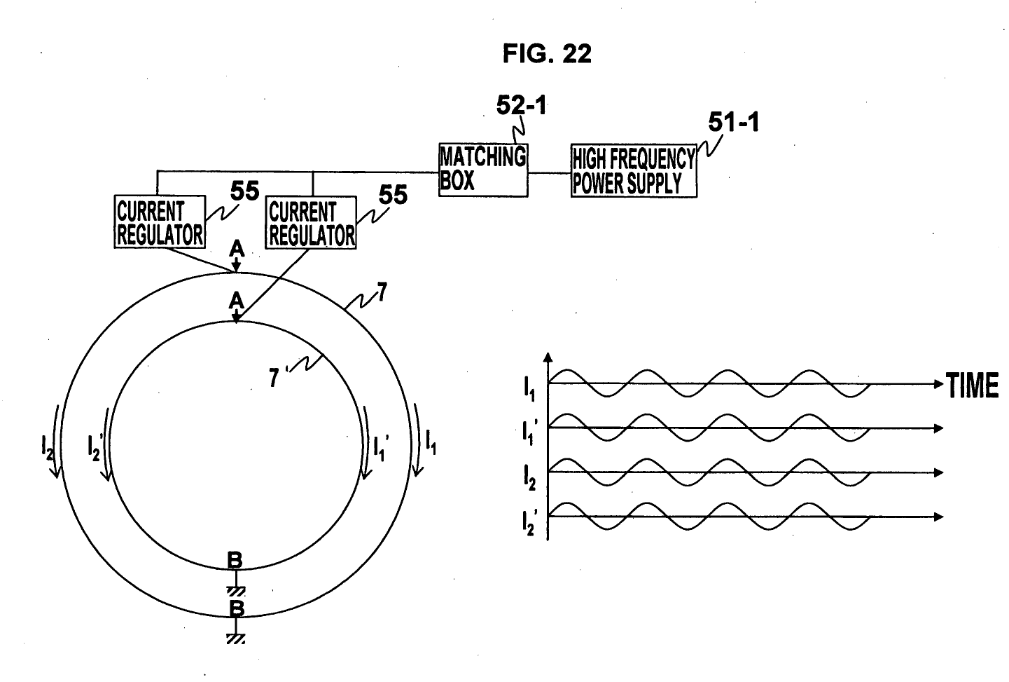

The fifteenth embodiment of the present invention will be described with reference to FIG. 22. FIG. 22 shows one embodiment of an arrangement where the length l of the high frequency induction antenna element is l<<λ/n, that is, when I₁A=I₁B, a simplest arrangement where n=2 and m=2 is adopted. The present arrangement adopts the arrangement shown in FIG. 12 to the inner antenna 7′ and the outer antenna 7. In the example, the currents I₁, I₁′, I₂ and I₂′ flown through the high frequency induction antenna elements can all be of the same phase. Accordingly, current can be supplied from a single power supply to the power feed point A of the inner antenna and the power feed point A of the outer antenna. In that case, it is preferable to insert a current regulator 55 for regulating the current supplied to the inner antenna and the outer antenna at the positions illustrated in the drawing. Of course, it is possible to supply currents from independent power supplies to the inner antenna 7′ and the outer antenna 7.

Similar to the case of the flat plate-shaped top member 12 of the vacuum chamber, even if the shape of the top member 12 of the vacuum chamber formed of insulating material is a trapezoidal rotated body, a hollow semispherical body or dome shape, or a cylindrical shape with a bottom, it is possible to arrange the high frequency induction antenna to the inner and outer circumferences thereof, or to the upper and lower area thereof or obliquely. As described with reference to FIG. 13, the position of the antenna with respect to the top member 12 of the vacuum chamber is extremely important in controlling the generation distribution of plasma and the diffusion distribution of plasma. In the same sense, the arrangement of the inner antenna and the outer antenna with respect to the top member 12 of the vacuum chamber is extremely important.

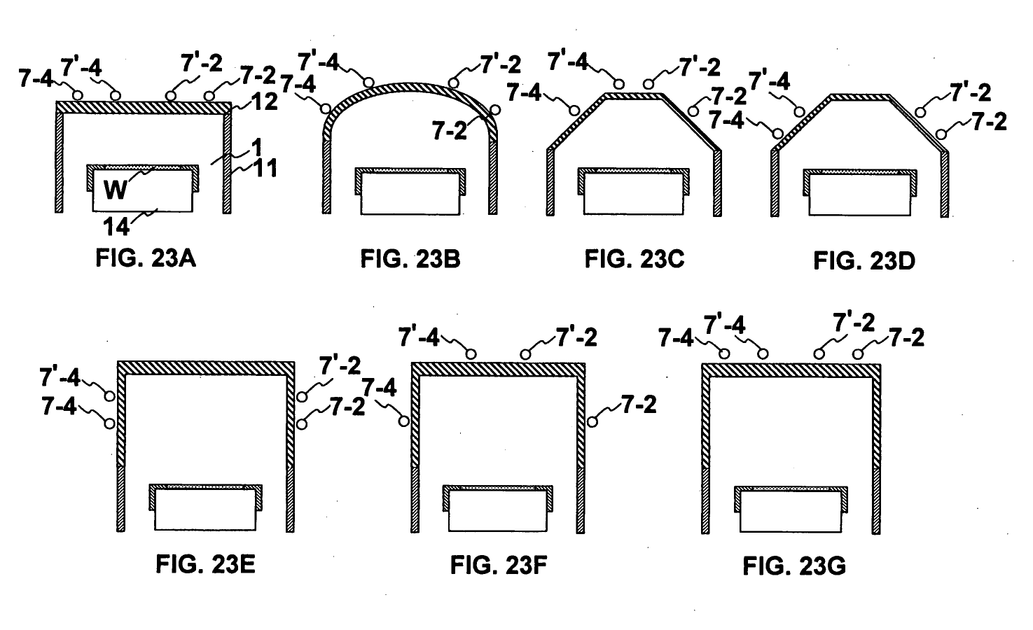

FIG. 23 shows the variations of arrangements of the inner antenna 7′ and the outer antenna 7 with respect to the top member 12 of the vacuum chamber. FIG. 23A illustrates an example where the inner antenna 7′ and the outer antenna 7 are arranged on the flat plate-shaped top member 12 of the vacuum chamber. This arrangement enables to create a more center-concentrated plasma distribution compared to the arrangement of FIG. 13A. Of course, if either one of the currents supplied to the inner antenna 7′ or the outer antenna 7 is 0 A, the arrangement of FIG. 23A will be equivalent to 13A. The flat plate-shaped top member 12 of the vacuum chamber only has a single plane (upper plane), so that the described arrangement is taken. FIG. 23B shows a variation of an arrangement of the inner antenna 7′ and the outer antenna 7 on a dome-shaped top member 12 of the vacuum chamber. The outer antenna and the inner antenna are arranged on a curved surface of the dome, to thereby improve the distribution controllability of plasma. Similar to the case of FIG. 23A, if either one of the currents supplied to the inner antenna 7′ or the outer antenna 7 is 0 A, the arrangement of FIG. 23B will be equivalent to FIG. 13A.

FIGS. 23C and 23D are variations of arrangements of the inner antenna 7′ and the outer antenna 7 on a top member 12 of the vacuum chamber having a trapezoidal rotated shape. The top member 12 of the vacuum chamber having a trapezoidal rotated shape has a slanted side plane and a flat upper plane, so that variations as illustrated in FIGS. 23C and 23D are enabled. FIG. 23C has the outer antenna 7 arranged on the slanted side plane and the inner antenna 7′ arranged on the upper plane. FIG. 23D has the inner antenna 7′ and the outer antenna 7 arranged on the slanted side plane. In both FIGS. 23C and 23D, if either one of the currents supplied to the inner antenna 7′ or the outer antenna 7 is set to 0 A, the arrangements will be equivalent to FIG. 13D. Furthermore, FIG. 23D enables to control the plasma distribution at the center portion further than FIG. 23C. Although not shown, it is also possible to arrange both antennas on the upper plane thereof.

FIGS. 23E, 23F and 23G show variations of arrangements of the inner antenna 7′ and the outer antenna 7 on the top member 12 of the vacuum chamber having a cylindrical shape with a bottom. The top member 12 of the vacuum chamber having a cylindrical shape has a perpendicular side wall and a wide and flat upper plane, so that the variations illustrated in FIGS. 23E, 23F and 23G are enabled. FIG. 23E has the inner antenna 7′ and the outer antenna 7 arranged on the side wall. FIG. 23F has the outer antenna 7 arranged on the side wall and the inner antenna 7′ arranged on the upper plane. According to FIGS. 23E and 23F, if either one of the currents supplied to the inner antenna 7′ or the outer antenna 7 is set to 0 A, the arrangements will be equivalent to FIG. 13E.

FIG. 23G has the outer antenna 7 and the inner antenna 7′ arranged on the upper plane. According to FIG. 23G, it seems as if either one of the currents supplied to the inner antenna 7′ or the outer antenna 7 is set to 0 A, the arrangement will be equivalent to FIG. 13A. However, according to FIG. 13A, the side wall is composed of a vacuum chamber formed of a conductor (which is grounded), whereas according to FIG. 23G, the side wall is composed of a top member 12 of the vacuum chamber formed of an insulating member (which is electrically floating), so that the distribution of the generated induction electric field differs. The variations of the shape of the top member 12 of the vacuum chamber and the number of sets and the arrangements of the high frequency induction antennas should be determined based on the process to which the generated plasma is applied.

In FIG. 1 (FIG. 2), the circular arc-shaped high frequency induction antenna elements 7-1, 7-2, 7-3 and 7-4 having divided a single circle into four parts are arranged on a single circumference. This arrangement that the antennas “are arranged on a circumference” is not a necessary arrangement for realizing the first content of the aforementioned necessary and sufficient conditions. For example, even if four linear high frequency induction antenna elements are arranged in a square shape, the first content of the aforementioned necessary and sufficient conditions can still be realized. Naturally, n-number of linear high frequency induction antenna elements satisfying n≧2 can be used to form a high frequency induction antenna 7 having n-sides (if n=2, the antenna elements should be arranged to face one another with a certain distance therebetween).

### Embodiment 16

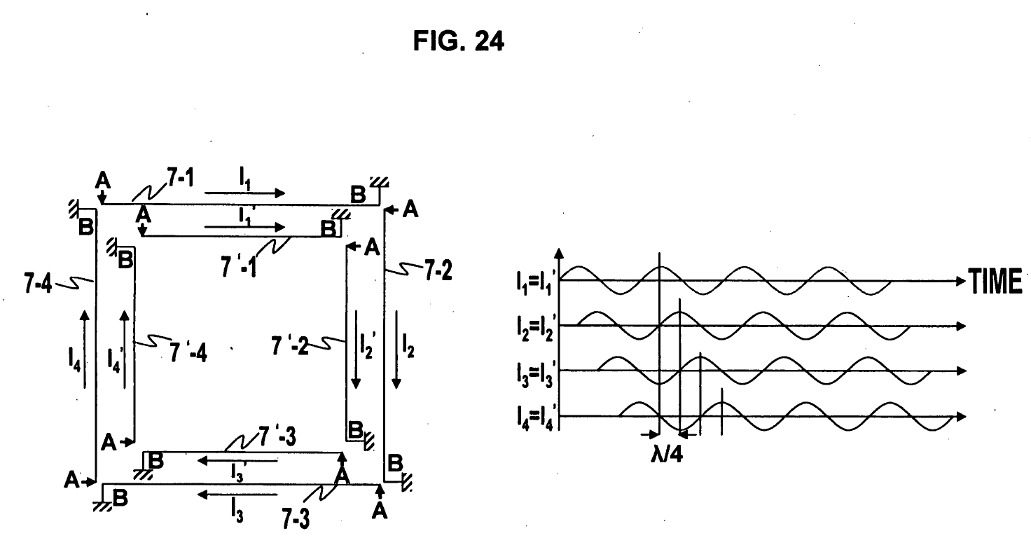

The sixteenth embodiment of the present invention will now be described with reference to FIG. 24. In this embodiment, the high frequency induction antenna elements 7-1 through 7-4 and 7′-1 through 7′-4 as shown in FIG. 19 are formed linearly, and the outer antenna 7 and the inner antenna 7′ of the respective sets are formed in a square shape. FIG. 24 illustrates an arrangement of the high frequency induction antenna in which the antenna division number is set to n=4 and the number of sets of the antenna is set to m=2. The high frequency induction antenna elements 7-1 through 7-4 arranged linearly and divided is arranged as the outer antenna 7, and the elements constitute a rectangle (square) where the division number of the antenna is four. The inner antenna 7′ is arranged similarly. This embodiment has changed the antenna structure shown in FIG. 19 to a square shape. However, by adopting a square shape, a square-shaped induction electric field is rotated. It is possible to understand that the shape of the electric field formed as a circle in FIG. 3 is turned into a square shape. However, a completely square-shaped electric field distribution does not exist. This is because an electric field is always formed of a differentiable curved surface. However, the arrangement of FIG. 24 has an effect in which the collapse of the induction electric field distribution from the square shape formed of the inner antenna is corrected by the outer electrode. In FIG. 24, the phase difference between the currents of the inner antenna and the outer antenna is 0°, but it can be of values other than 0°, similar to the case of FIG. 19.

### Embodiment 17

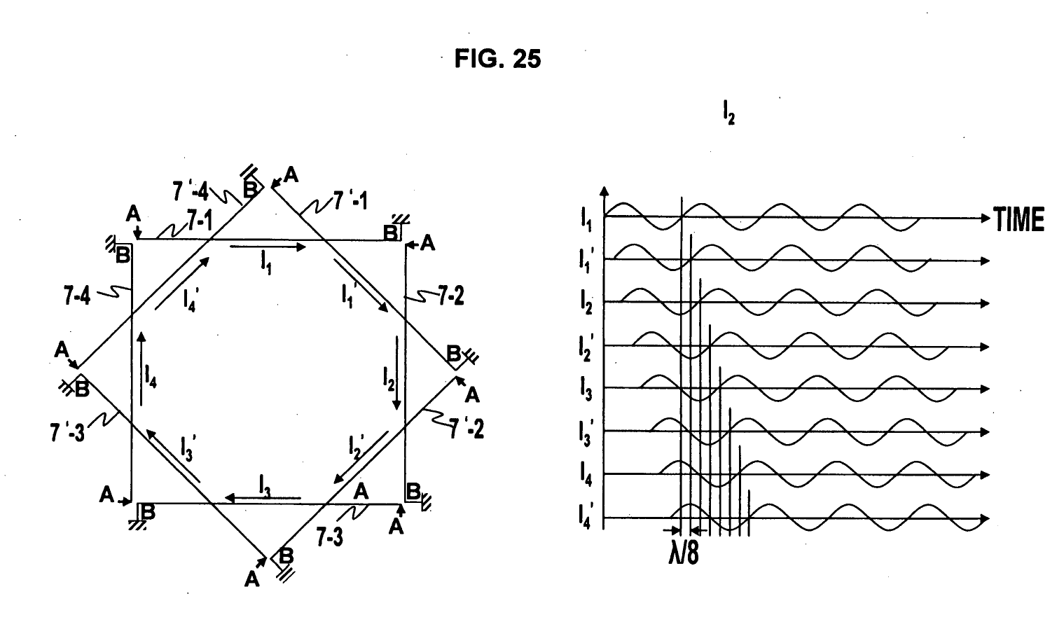

The seventeenth embodiment of the present invention will be described with reference to FIG. 25. This embodiment relates to the arrangement of high frequency induction antennas in which the induction electric field is enabled to rotate in a more complete square shape than the arrangement of FIG. 24. According to this arrangement, the idea described with reference to FIG. 20 is applied to a polygonal shape with n sides, wherein the phases of currents supplied to the respective antenna elements are the same as those of FIG. 20. That is, the outer (first) antenna 7 composed of high frequency induction antenna elements 7-1 through 7-4 and the inner (second) antenna 7′ composed of high frequency induction antenna elements 7′-1 through 7′-4 are displaced by 45°, forming an induction electric field rotating in the right direction. According to the first antenna 7, linear-shaped high frequency induction antenna elements 7-1 through 7-4 are arranged in a square shape. Currents with a λ/4 phase shift are supplied from the power feed ends A to the respective high frequency induction antenna elements 7-1 through 7-4, and the grounded ends B thereof are grounded. Similarly, the second antenna 7′ has the linear high frequency induction antenna elements 7′-1 through 7′-4 arranged in a square shape. Currents with a λ/4 phase shift are supplied from the power feed ends A to the respective high frequency induction antenna elements 7′-1 through 7′-4, and the grounded ends B thereof are grounded. The corresponding high frequency induction antenna elements 7-1 and 7′-1 have currents with a λ/8 phase difference supplied thereto, and other corresponding high frequency induction antenna elements 7-2 and 7′-2, 7-3 and 7′-3 and 7-4 and 7′-4 similarly have currents with a λ/8 phase difference supplied thereto. The first antenna 7 and the second antenna 7′ are superposed one above the other, and are displaced by 45°. According to this arrangement, currents I₁, I₁′, I₂, I₂′, I₃, I₃′, I₄ and I₄′ with λ/8 phase shifts are respectively supplied to neighboring high frequency induction antenna elements, so that an induction electric field rotated in the right direction having a shape more close to a square compared to FIG. 24 can be formed.

As described, the arrangements of the high frequency induction antenna from embodiment 5 to embodiment 17 are all varied, but as shown in FIG. 5, they all form a same induction electric field distribution E that rotates in the right direction with respect to the direction of the magnetic field lines. All embodiments are variations satisfying the first point of the aforementioned necessary and sufficient conditions. Furthermore, the arrangements can be applied to any shape of the top member 12 of the vacuum chamber illustrated in embodiments 2 through 4.

The features of the present invention illustrated with reference to FIGS. 2, 13, 18 and 23 will be summarized once again. According to the present invention, there are many plasma distribution control functions, including the division number n of the antenna, the shape of the top member 12 of the vacuum chamber, the number of sets m of the high frequency induction antennas, and the arrangement of the antenna with respect to the top member 12 of the vacuum chamber. However, these features are possibly realized by the arrangement of apparatuses utilizing prior art ICP sources. What is most important according to the present invention with respect to plasma distribution control is that the a tuning knob electrically controllable from the exterior, which is the ECR plane, is introduced to the above-mentioned flexible plasma controllability realized by the arrangement of the apparatus. By creating a rotating induction electric field and realizing ECR discharge in an ICP source, it not only becomes possible to realize an arrangement capable of generating plasma with superior plasma ignition property with a lower gas pressure, but also to provide a superior plasma controllability utilizing the ECR plane that can be controlled from the exterior. There has not been any plasma source according to the prior art having such flexible plasma controllability as the present invention.

According further to the present invention, since a high frequency induction magnetic field for driving currents is formed constantly in the processing chamber, so that the ignition property of plasma is improved and a high density plasma can be obtained. Further according to the present invention, the length of the high frequency induction antenna can be controlled, enabling the apparatus to cope with demands to increase the diameter of the apparatus, and to improve the plasma uniformity in the circumferential direction.

FIG. 1 shows a Faraday shield 9. Since the Faraday shield essentially has a function to suppress capacitive coupling between the antenna for radiating high frequency and plasma, it cannot be used in capacitively coupled ECR plasma sources (refer for example to patent document 5). According to the present invention, the Faraday shield can be used similar to normal ICP sources. However, according to the present invention, the use of a “Faraday shield” is not an indispensible arrangement, since it is not related to the aforementioned necessary and sufficient conditions. However, similar to normal ICP sources, the Faraday shield is useful from the viewpoint of industrial applicability. The Faraday shield does not have much influence on the induction magnetic field H radiated from the antenna (that is, the induction electric field E), and functions to block capacitive coupling between the antenna and plasma. The Faraday shield should be grounded to block the capacitive coupling more completely. Normally in ICP sources, when capacitive coupling is blocked, the ignition property of plasma is further deteriorated. However, according to the present invention, highly efficient ECR heating via the induction electric field E caused by inductive coupling is utilized, and further in the arrangement where n 3, there is no moment where the induction electric field E becomes equal to 0, so that a superior ignition property is achieved even if capacitive coupling is blocked completely. This is one of the most important features of the present invention. However, due to various reasons, it is possible to connect an electric circuit to the Faraday shield, and to control the high frequency voltage generated in the Faraday shield to zero or above zero.

One of the advantages of applying a high frequency potential to the Faraday shield is that a self bias can be applied to the inner side of the top member 12 of the vacuum chamber exposed to plasma. If a large amount of reaction products are attached to the inner surface of the top member 12 of the vacuum chamber, the attached reaction products may be detached from the surface and fall on the object to be processed W. Further, if conductive reaction products are attached to this surface, the intensity of the high frequency induction electric field formed by the high frequency induction antenna or the distribution thereof may vary with time, making it impossible to continue processing of the object to be processed. As described, reaction products attached to the inner side of the top member 12 of the vacuum chamber causes many problems in processing a product, but these problems can be avoided by applying a self bias to this surface to prevent reaction products from attaching thereto, according to which a stable product processing can be continuously performed for a long period of time, and an apparatus having superior mass-production stability can be obtained. What is important here is that a uniform self bias voltage is applied to the inner side of the top member 12 of the vacuum chamber, that is, that a uniform high frequency voltage is applied throughout the Faraday shield.

A few techniques for applying high frequency voltage to the Faraday shield have been developed. When such prior art methods are applied to the present invention, a failure occurs. Examples of the developed art are disclosed in patent document 7: Japanese patent application laid-open publication No. 11-74098 (U.S. Pat. No. 6,388,382), and patent document 8: U.S. Pat. No. 5,811,022. The characteristics of these methods are that a voltage generated using the plasma generating power supply is applied to the Faraday shield. Naturally, the frequency of the high frequency voltage generated in the Faraday shield is equal to the frequency of the plasma generating high frequency power supply. Two problems occur when this method is applied to the present invention. The first problem is that it is impossible to realize both the phase control of the n-numbers of currents with respect to the n-numbers of antenna elements, and to takeout a voltage having a single phase from the power supply used to perform the phase control. The practical advantages of the present invention will be lost, since either the current flown to the antenna elements or the voltage applied to the Faraday shield is subjected to significant restriction. The second problem is that if the frequency of the plasma generating high frequency power supply is VHF, for example, similar to the teachings of non-patent document 1, an uneven voltage distribution occurs throughout the Faraday shield due to the wavelength shortening effect. In other words, it becomes impossible to apply a uniform self bias to the inner surface of the top member 12 of the vacuum chamber.

In order to solve these problems, the high frequency power supply for applying voltage to the Faraday shield must be an independent power supply from the high frequency power supply for generating plasma. Further, the frequency of the high frequency power supply for applying voltage to the Faraday shield must be a frequency capable of causing a uniform voltage distribution throughout the Faraday shield (for example, 30 MHz or smaller).

### Embodiment 18

A method for applying a high frequency voltage to the Faraday shield from an independent high frequency power supply is disclosed in patent document 9: Japanese patent application laid-open publication No. 2006-156530. The characteristics of the present method is that a frequency same as the frequency of the high frequency bias applied to the object to be processed W is used to apply phase-controlled high frequency voltage to the object to be processed W and the Faraday shield respectively. As taught in the invention, the Faraday shield and the object to be processed W are respectively capacitively coupled with plasma, and has the same electrode arrangement as a parallel plate capacitively coupled plasma source. The application of a high frequency voltage of the same frequency having voltage phase controlled to this system is a very advantageous method, with an effect to prevent abnormal diffusion of plasma. However, the application of the disclosed arrangement to the present invention cannot solve the second problem mentioned earlier. This is because the Faraday shield is also capacitively coupled with the high frequency induction antenna, so that even by adopting this arrangement, it is not possible to prevent an uneven voltage distribution of the same frequency as the plasma generating high frequency power supply from being generated in the Faraday shield.

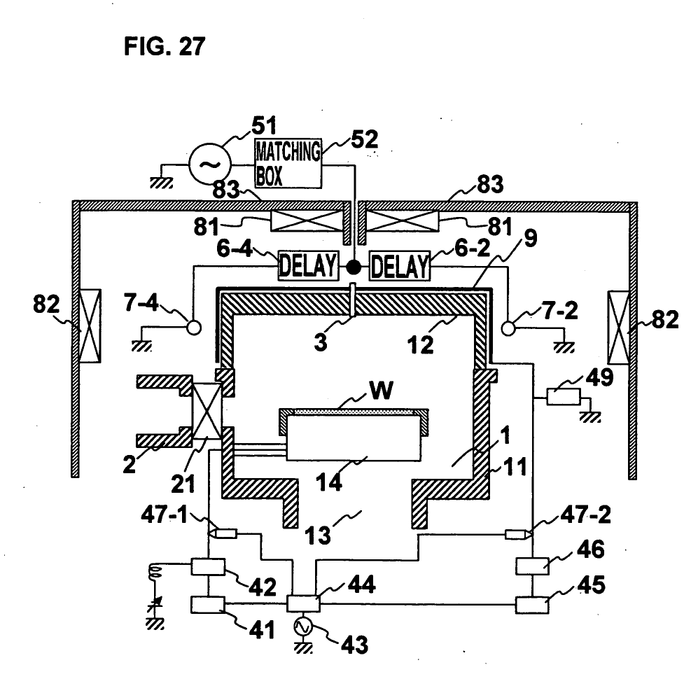

The method for applying a high frequency voltage to the Faraday shield having solved the above-mentioned problems will be described as the eighteenth embodiment of the present invention with reference to FIG. 27. The plasma generating method according to FIG. 27 is the same as FIG. 16, but it can also be applied in the same manner to FIGS. 1, 14 and 15. According to the arrangement of FIG. 27, the output of the oscillator 43 is entered to a phase controller 44. The phase controller 44 observes the phase of the high frequency voltages applied finally to the object to be processed W and the Faraday shield 9 using phase detectors 47-1 and 47-2, and high frequency signals controlled to the necessary phase is output to the bias high frequency power supply 41 and the Faraday shield high frequency power supply 45. The high frequency power amplified by the two high frequency power supplies 41 and 45 are respectively applied via matching boxes 42 and 46 to the object to be processed W and the Faraday shield 9.

At this time, a filter 49 must be provided so as not to cause an uneven voltage distribution having the same frequency as the plasma generating high frequency to be generated in the Faraday shield 9. The filter 49 must have a finite (not zero) impedance at least with respect to the high frequency output from the oscillator 43, and must have a small enough impedance that could be assumed as zero with respect to the plasma generating high frequency. In other words, the filter must be a high-pass filter or a notch filter capable of realizing an impedance that can be assumed as zero with respect to the plasma generating high frequency. However, it is not enough for a single filter 49 to be inserted to the power feed line of the Faraday shield 9, as disclosed in FIG. 27. This is extremely important, since the voltage having the same frequency as the plasma generating high frequency has a distribution on the Faraday shield 9, so that even if the high frequency voltage of the area where the filter is inserted is grounded (and the voltage becomes 0 V), does not mean that the high frequency voltage at other areas is grounded. Therefore, the present filter 49 must be inserted to multiple locations within the Faraday shield 9.

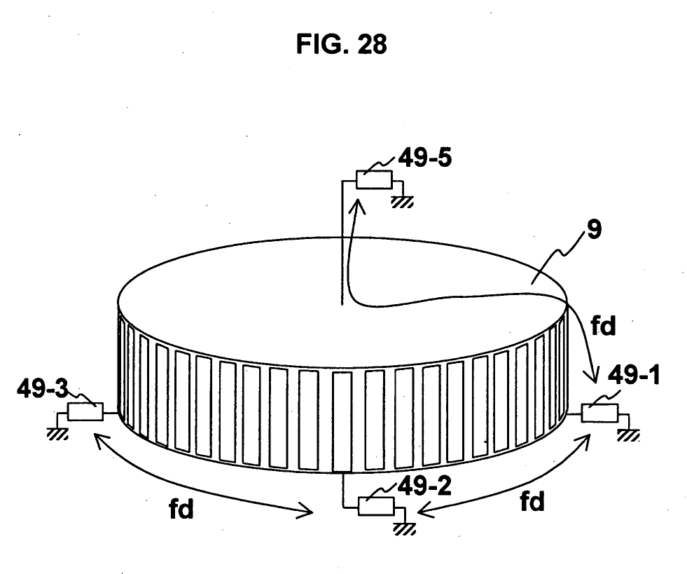

A state in which a plurality of filters 49 are inserted to various locations within the Faraday shield 9 is shown in FIG. 28. At first, the Faraday shield 9 is a component formed of a conductor body formed to correspond to the shape of the top member 12 of the vacuum chamber shown in FIG. 27. A large number of slits are formed perpendicularly with respect to the direction of the high frequency induction antenna on the plane opposed to the high frequency induction antenna 7 (the side wall in FIG. 27). Since the Faraday shield 9 is a conductor, it enables to block the capacitive coupling between the high frequency induction antenna and the plasma, and the large number of slits prevent the revolving current from flowing to the Faraday shield 9 in the direction of the high frequency induction antenna and to cause inductive coupling of the high frequency induction antenna and plasma. This is a well-known basic principle of a Faraday shield. FIG. 28 shows an example where the filters 49 are inserted to five locations of the Faraday shield (49-1, 49-2, 49-3, 49-4 not shown and 49-5). The condition to be satisfied by the insertion locations of the filters 49 is that all the distances fd along the surface of the Faraday shield 9 between the filters are sufficiently smaller than the wavelength λ of the plasma generating high frequency, that is, fd<<λ. The number of locations for inserting filters 49 is not limited to five, and the number must be determined so as to satisfy fd<<λ.

### Embodiment 19

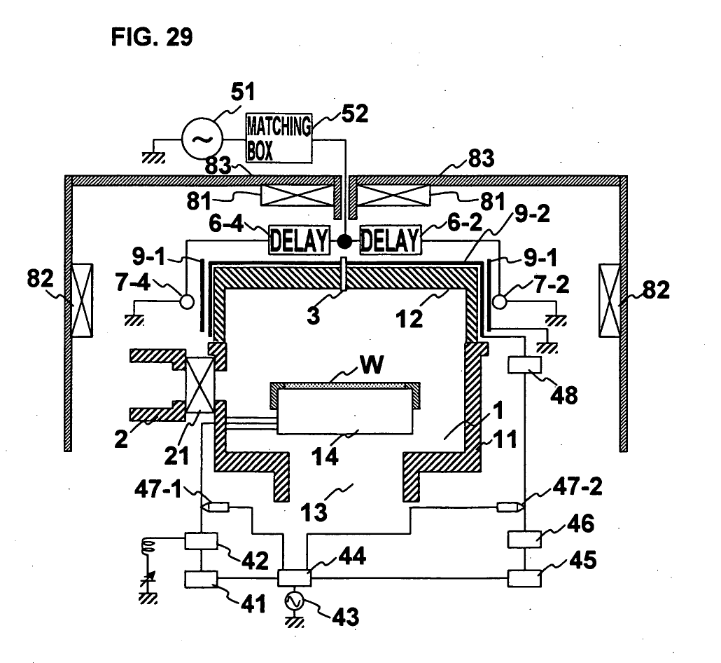

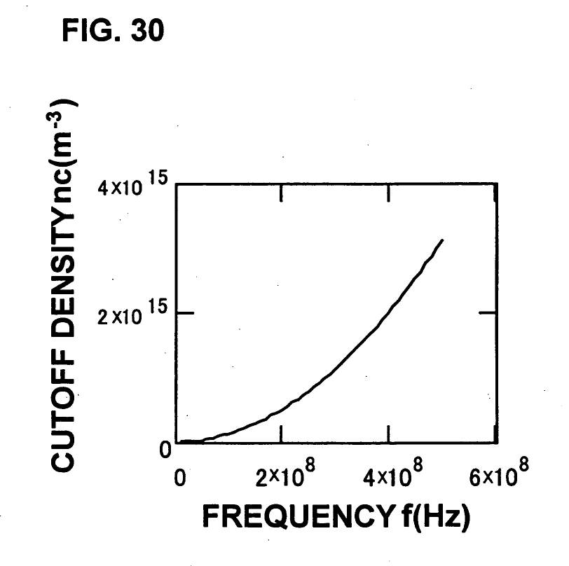

In the method shown in FIG. 27, a plurality of filters 49 must be connected to the Faraday shield 9, and the arrangement becomes complex, but another embodiment (nineteenth embodiment) for preventing such complication will be shown in FIG. 29. Compared to the embodiment shown in FIG. 27, according to the embodiment shown in FIG. 29, the Faraday shield 9 is divided into two parts, an outer Faraday shield 9-1 and an inner Faraday shield 9-2. In other words, the embodiment adopts a double Faraday shield. The outer Faraday shield 9-1 is opposed to the high frequency induction antenna 7, and by grounding the same, the capacitive coupling between the high frequency induction antenna 7 and the plasma is blocked. The Faraday shield 9-1 should be grounded throughout the whole circumference of the Faraday shield 9-1, for example, so as not to cause high frequency voltage to be generated in the Faraday shield 9-1. Naturally, slits similar to those of FIG. 28 are formed to the Faraday shield 9-1, so as not to prevent inductive coupling of the high frequency induction antenna 7 and plasma. By disposing the outer Faraday shield 9-1, no high frequency voltage caused by the plasma generating high frequency is generated to the inner Faraday shield 9-2. Accordingly, the function of the inner Faraday shield 9-2 having slits similar to FIG. 28 is to cause inductive coupling of the high frequency induction antenna 7 and plasma, and to apply a high frequency voltage output by the phase-controlled Faraday shield high frequency power supply 45 to the top member 12 of the vacuum chamber. Based on methods illustrated in FIGS. 27 and 29, it becomes possible to apply a uniform high frequency voltage to the top member 12 of the vacuum chamber via the Faraday shield 9 using the inductively coupled ECR plasma source.

FIG. 1 shows upper coil 81 and lower coil 82 as two electromagnets and a yoke 83 as components constituting the magnetic field. However, what is indispensible according to the present invention is that a magnetic field satisfying the aforementioned necessary and sufficient conditions is realized, and therefore, the yoke 83 and the two electromagnets are not necessary arrangements. As long as the aforementioned necessary and sufficient conditions are satisfied, only the upper coil 81 (or the lower coil 82) can be used. The means for generating the magnetic field can be either an electromagnet or a stationary magnet, or a combination of electromagnet and stationary magnet.

FIG. 1 shows a gas inlet 3, a gate valve 21, a wafer bias (bias power supply 41 and matching box 42) other than the elements mentioned earlier, but these components are unrelated to the aforementioned necessary and sufficient conditions, and thus are not indispensible components according to the present invention. The gas inlet is necessary for generating plasma, but the position thereof can be on the wall of the vacuum chamber, or on the electrode 14 on which the wafer W is placed. Further, the gas can be injected either in a planar manner or through a number of points. The gate valve 21 is illustrated only with the aim to show how the wafer is carried when the apparatus is industrially applied. Further, in actual industrial application of the plasma processing apparatus, the wafer bias (bias power supply 41 and matching box 42) is not necessary required, and it is not indispensible for industrial application of the present invention.

According to the present invention, the induction electric field E formed by the high frequency induction antenna rotates in the right direction with respect to the magnetic field lines of the magnetic field. The shape of the rotation plane is determined by the arrangement of the high frequency induction antenna, and can be a circle or an oval, for example. Therefore, a center axis of rotation necessarily exists. In industrial application, such center axis exists in the magnetic field B, the object to be processed (such as a circular wafer or a square glass substrate), the vacuum chamber, the gas injection port, the electrode for holding the object to be processed, and the evacuation port. According to the present invention, the center axes of these components are not required to correspond, and they are not necessary components, since they are unrelated to the aforementioned necessary and sufficient conditions. However, if the uniformity of surface processing of the object to be processed (such as the etching rate, the deposition rate and the contour) becomes an issue, it is preferable that these center axes correspond.

What is claimed is:

1. A plasma processing apparatus comprising a vacuum chamber constituting a vacuum processing chamber for storing a sample, a gas inlet for feeding processing gas into the vacuum processing chamber, a high frequency induction antenna for forming an induction electric field within the vacuum processing chamber, a magnetic field coil for forming a magnetic field in the vacuum processing chamber, a plasma generating high frequency power supply for supplying a high frequency current to the high frequency induction antenna, and a power supply for supplying power to the magnetic field coil for subjecting a sample to plasma processing by supplying the high frequency current from the high frequency power supply to the high frequency induction antenna and turning the gas supplied into the vacuum processing chamber to plasma;
wherein the vacuum processing chamber includes a vacuum processing chamber top member formed of a dielectric body airtightly fixed to an upper portion of the vacuum chamber, and a Faraday shield disposed between the high frequency induction antenna and the vacuum processing chamber;
the high frequency induction antenna is divided into n-numbers (integral number of n≧2) of high frequency induction antenna elements, wherein the respective high frequency induction antenna elements are arranged tandemly, having a plurality of sets of tandemly arranged high frequency induction antenna elements, each high frequency induction antenna element of the respective sets of high frequency induction antenna having supplied thereto a high frequency current sequentially delayed by λ (wavelength of the high frequency power supply)/n in order in a fixed direction, so that a rotating induction electric field E that rotates in a right direction with respect to the direction of magnetic field lines of a magnetic field B formed by supplying power to the magnetic field coil is formed by the high frequency current, the rotational frequency of the rotating induction electric field E corresponding to the electron cyclotron frequency via the magnetic field B, and a plurality of sets (the number of sets being a natural number of m≧1) of high frequency induction antennas and the magnetic field are arranged so that a relationship of E×B≠0 is satisfied at an arbitrary portion between the induction electric field E and the magnetic field B to generate plasma, the plasma being used to subject the sample to plasma processing.

2. The plasma processing apparatus according to claim 1, wherein
the Faraday shield is structured to cover a whole body of the vacuum processing chamber top member.

3. The plasma processing apparatus according to claim 1, further comprising:
an electrode for holding a sample, a bias high frequency power supply for applying high frequency power to the electrode, a Faraday shield high frequency power supply for applying high frequency power to the Faraday shield, an oscillator for supplying high frequency to the bias high frequency power supply and the Faraday shield high frequency power supply, and a phase controller for controlling a phase difference between the bias high frequency power supply and the Faraday shield high frequency power supply.

4. The plasma processing apparatus according to claim 3, wherein
the frequency of the bias high frequency power supply is lower than the frequency of the plasma generating high frequency power supply.

5. The plasma processing apparatus according to claim 3, wherein
the Faraday shield is grounded via a plurality of filters, and an impedance between the Faraday shield and the ground potential is substantially 0Ω when observed from the frequency of the plasma generating high frequency power supply, whereas the impedance is not substantially 0Ω when observed from the frequency of the Faraday shield high frequency power supply.

6. The plasma processing apparatus according to claim 1, wherein
the Faraday shield has a structure composed of a first Faraday shield arranged close to the high frequency induction antenna and a second Faraday shield arranged close to the vacuum processing chamber top member.

7. The plasma processing apparatus according to claim 6, wherein
the first Faraday shield is arranged only at the circumference of the high frequency induction antenna.

8. The plasma processing apparatus according to claim 6, wherein
the second Faraday shield has a structure covering the whole body of the vacuum processing chamber top member.

9. The plasma processing apparatus according to claim 6, further comprising:
an electrode for holding a sample, a bias high frequency power supply for applying high frequency power to the electrode, a Faraday shield high frequency power supply for applying high frequency power to the second Faraday shield, an oscillator for supplying high frequency to the bias high frequency power supply and the Faraday shield high frequency power supply, and a phase controller for controlling a phase difference between the bias high frequency power supply and the Faraday shield high frequency power supply.

10. The plasma processing apparatus according to claim 9, wherein
the frequency of the bias high frequency power supply is lower than the frequency of the plasma generating high frequency power supply.

11. The plasma processing apparatus according to claim 9, wherein
the first Faraday shield is a ring-shaped conductor with slits, the whole circumference of which is grounded, and the impedance between the first Faraday shield and the ground potential is substantially 0Ω when observed from the frequency of the plasma generating high frequency power supply.
